(19) United States
(12) Patent Application Publication
(10) Pub. No.: US 2025/0324882 A1
(43) Pub. Date: Oct. 16, 2025

(54) DISPLAY DEVICE AND METHOD FOR FABRICATING THE SAME

(71) Applicant: Samsung Display Co., LTD., Yongin-si (KR)

(72) Inventors: Jae Been LEE, Yongin-si (KR); Dae Ho SONG, Yongin-si (KR); Mi Yeon CHO, Yongin-si (KR); Ye Hwan CHOI, Yongin-si (KR)

(21) Appl. No.: 19/019,205

(22) Filed: Jan. 13, 2025

(30) Foreign Application Priority Data
Apr. 16, 2024 (KR) 10-2024-0050560

(51) Int. Cl. H10K 59/80; H10K 59/12; H10K 59/123

(52) U.S. Cl. CPC H10K 59/80517; H10K 59/1201; H10K 59/123

(57) ABSTRACT

The present disclosure relates to a display device capable of providing light of high luminance, and a method of fabricating the same. According to one or more embodiments, a display device includes a substrate, an anode electrode above the substrate, and including a first layer, a second layer on the first layer, a third layer on an upper surface and a side surface of the second layer, and a fourth layer connected to the first layer, and on an upper surface of the first layer, an upper surface of the third layer, and a side surface of the third layer, a light-emitting stack above the anode electrode, and a cathode electrode above the light-emitting stack.

### CROSS-REFERENCE TO RELATED APPLICATION

The present application claims priority to, and the benefit of, Korean Patent Application No. 10-2024-0050560, filed on Apr. 16, 2024, in the Korean Intellectual Property Office, the entire disclosure of which is incorporated herein by reference.

### BACKGROUND

### 1. Field

The present disclosure relates to a display device capable of providing light of relatively high luminance, and a method of fabricating the same.

### 2. Description of the Related Art

A head-mounted display (HMD) is an image display device that is worn on a user's head in the form of glasses or a helmet, and that forms a focus at a distance close to user's eyes in front of the user's eyes. The head-mounted display may implement virtual reality (VR) or augmented reality (AR).

The head-mounted display magnifies and displays an image displayed by a small display device using a plurality of lenses. Therefore, a display device applied to the head-mounted display needs to provide a high-resolution image, for example, an image having a resolution of about 3000 pixels per inch (PPI) or more. To this end, an organic light-emitting diode on silicon (OLEDoS), which is a small organic light-emitting display device having a high resolution, has been used as the display device applied to the head-mounted display. The OLEDoS is a device that displays an image by placing organic light-emitting diodes (OLEDs) on a semiconductor wafer substrate on which complementary metal oxide semiconductors (CMOSs) are located.

### SUMMARY

Aspects of the present disclosure provide a display device capable of providing light of high luminance, and a method of fabricating the same.

According to one or more embodiments, a display device includes a substrate, an anode electrode above the substrate, and including a first layer, a second layer on the first layer, a third layer on an upper surface and a side surface of the second layer, and a fourth layer connected to the first layer, and on an upper surface of the first layer, an upper surface of the third layer, and a side surface of the third layer, a light-emitting stack above the anode electrode, and a cathode electrode above the light-emitting stack.

The second layer and the third layer may be surrounded by the first layer and the fourth layer.

The first layer may be connected to a transistor through a via.

The fourth layer may be connected to the light-emitting stack.

The fourth layer may be directly connected to the first layer.

The fourth layer may be directly connected to the upper surface of the first layer.

The second layer may be at a central portion of the upper surface of the first layer.

The first layer may contain titanium, wherein the second layer contains aluminum, wherein the third layer contains aluminum oxide, and wherein the fourth layer contains a transparent conductive material.

The transparent conductive material may include indium tin oxide.

The anode electrode may further include a fifth layer between the third layer and the fourth layer.

The fifth layer may include an inorganic layer.

The anode electrode may be provided in plurality and may include a first anode electrode of a first pixel, a second anode electrode of a second pixel, and a third anode electrode of a third pixel.

The fifth layer of the first anode electrode, the fifth layer of the second anode electrode, and the fifth layer of the third anode electrode have different respective thicknesses.

The display device may further include a first color filter above the first anode electrode, a second color filter above the second anode electrode, and a third color filter above the third anode electrode.

The first color filter may be configured to transmit red light, wherein the second color filter is configured to transmit green light, and wherein the third color filter is configured to transmit blue light.

The thickness of the fifth layer of the second anode electrode may be less than the thickness of the fifth layer of the first anode electrode, and may be greater than the thickness of the fifth layer of the third anode electrode.

According to one or more embodiments of the disclosure, a method of fabricating a display device includes forming an insulating layer above a substrate, forming a first material layer above the insulating layer, forming a first photoresist pattern having a side surface of a reverse tapered shape above the first material layer, forming a second material layer including a first sub-material layer above the first material layer, and a second sub-material layer above the first photoresist pattern, forming a third layer above the first sub-material layer and above the second sub-material layer to be separated by the first photoresist pattern, removing the first photoresist pattern such that a second layer above the first material layer remains, forming a fourth material layer above the third layer, forming a second photoresist pattern above the fourth material layer, selectively removing the fourth material layer and the first material layer using the second photoresist pattern as a mask such that a fourth layer and a first layer remain, removing the second photoresist pattern such that an anode electrode including the first layer, the second layer, the third layer, and the fourth layer remains, forming a pixel-defining film above the anode electrode, forming a light-emitting stack above the pixel-defining film and the anode electrode, and forming a cathode electrode above the light-emitting stack.

The second layer may be on the first layer, wherein the third layer is on an upper surface and a side surface of the second layer, and wherein the fourth layer is on an upper surface of the first layer, an upper surface of the third layer, and a side surface of the third layer.

The second layer and the third layer may be surrounded by the first layer and the fourth layer.

The fourth layer may be directly connected to the first layer.

The fourth layer may be directly connected to an edge of the first layer.

The second layer may be at a central portion of an upper surface of the first layer.

The first layer may contain titanium, wherein the second layer contains aluminum, wherein the third layer contains aluminum oxide, and wherein the fourth layer contains a transparent conductive material.

The method may further include forming a fifth layer between the third layer and the fourth layer.

The fifth layer may include an inorganic layer.

A display device according to one or more embodiments may have relatively excellent reflectivity (for example, excellent reflectivity by an aluminum layer), and in addition, may have high transmittance (for example, high transmittance based on an omission of TiN layer). Accordingly, the display device according to one or more embodiments may provide light of high luminance even with low power.

The effects of the present disclosure are not limited to the above-described aspects, and other aspects that are not described herein will become apparent to those skilled in the art from the following description.

### BRIEF DESCRIPTION OF THE DRAWINGS

The above and other aspects of the present disclosure will become more apparent by describing in detail embodiments thereof with reference to the attached drawings, in which:

FIG. 1 is an exploded perspective view illustrating a display device according to one or more embodiments;

FIG. 2 is a layout diagram illustrating an example of the display panel illustrated in FIG. 1;

FIG. 3 is an equivalent circuit diagram of a first pixel according to one or more embodiments;

FIG. 4 is a layout diagram illustrating an example of a display panel according to one or more embodiments;

FIG. 5 is a layout diagram illustrating examples of a display area of FIG. 4;

FIG. 6 is a cross-sectional view illustrating an example of the display panel taken along the line X-X′ of FIG. 5;

FIG. 7 is a cross-sectional view of a display device according to one or more embodiments;

FIGS. 8 to 17 are cross-sectional views of a process for describing a method for fabricating a display device according to one or more embodiments;

FIG. 18 is a cross-sectional view of a display device according to one or more other embodiments;

FIG. 19 is a diagram for describing a resonance distance for each pixel in a display device according to one or more embodiments;

FIG. 20 is a perspective view illustrating a head-mounted display according to one or more embodiments;

FIG. 21 is an exploded perspective view illustrating an example of the head-mounted display of FIG. 20; and

FIG. 22 is a perspective view illustrating a head-mounted display according to one or more other embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

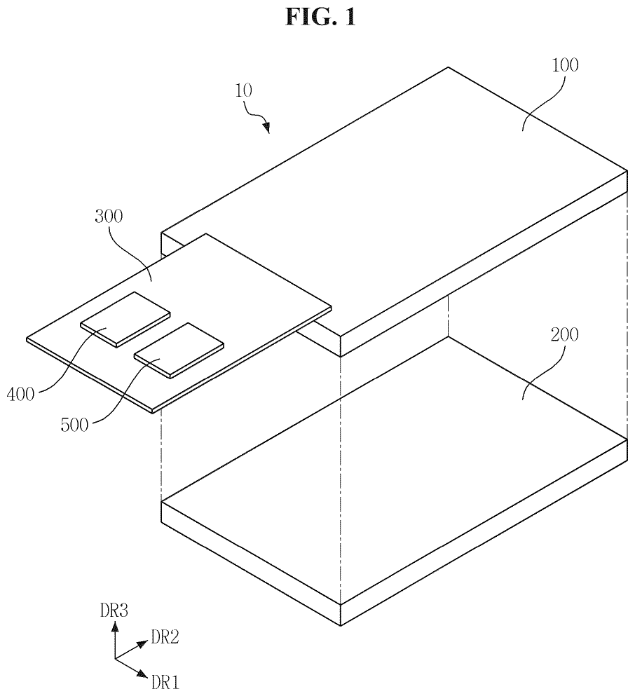

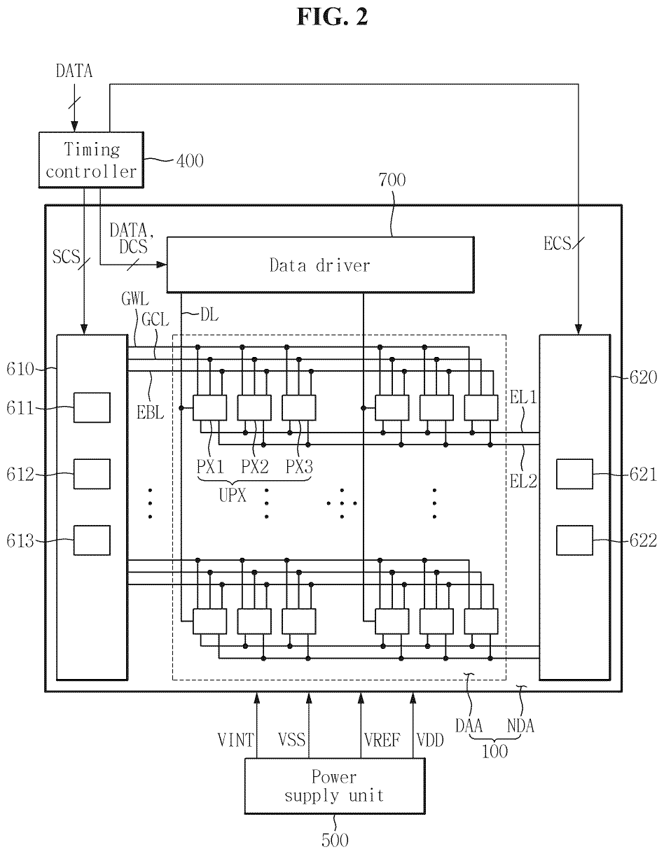

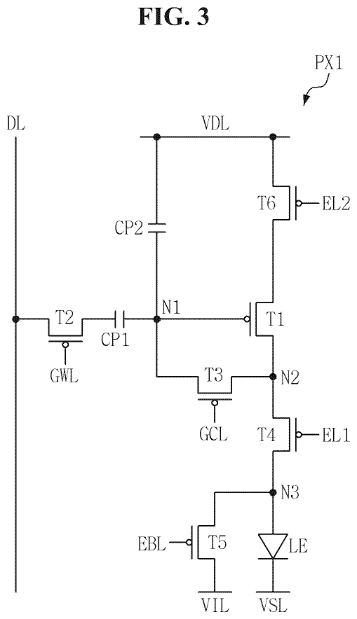

FIG. 1 is an exploded perspective view illustrating a display device according to one or more embodiments. FIG. 2 is a layout diagram illustrating an example of the display panel illustrated in FIG. 1. FIG. 3 is an equivalent circuit diagram of a first pixel according to one or more embodiments.

Referring to FIGS. 1 and 2, a display device 10 according to one or more embodiments is a device that displays a moving image or a still image. The display device 10 according to one or more embodiments may be applied to portable electronic devices, such as mobile phones, smartphones, tablet personal computers (PCs), mobile communication terminals, electronic notebooks, electronic books, portable multimedia players (PMPs), navigation devices, and ultra-mobile PCs (UMPCs). For example, the display device 10 according to one or more embodiments may be applied as a display unit of televisions, laptop computers, monitors, billboards, or the Internet of Things (IOTs). Alternatively, the display device 10 according to one or more embodiments may be applied to smart watches, watch phones, or head-mounted displays (HMDs) for implementing virtual reality and augmented reality.

The display device 10 according to one or more embodiments includes a display panel 100, a heat dissipation layer 200, a circuit board 300, a timing controller 400, and a power supply unit 500.

The display panel 100 may have a shape similar to a rectangular shape in plan view. For example, the display panel 100 may have a shape similar to a rectangular shape, in plan view, having short sides in a first direction DR1 and long sides in a second direction DR2 crossing the first direction DR1. In the display panel 100, a corner where the short side in the first direction DR1 and the long side in the second direction DR2 meet may be rounded with a curvature (e.g., predetermined curvature) or right-angled. A shape of the display panel 100 in plan view is not limited to the rectangular shape, and may be a shape similar to other polygonal shapes, a circular shape, or an elliptical shape. A shape of the display device 10 in plan view may follow the shape of the display panel 100 in plan view, but the present disclosure is not limited thereto.

The display panel 100 may include a display area DAA that displays an image, and a non-display area NDA that does not display an image, as illustrated in FIG. 2.

The display area DAA includes a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1, and may be located in the second direction DR2. The plurality of data lines DL may extend in the second direction DR2, and may be located in the first direction DR1.

The plurality of scan lines SL includes a plurality of write scan lines GWL, a plurality of control scan lines GCL, and a plurality of bias scan lines EBL. The plurality of emission control lines EL include a plurality of first emission control lines EL1 and a plurality of second emission control lines EL2.

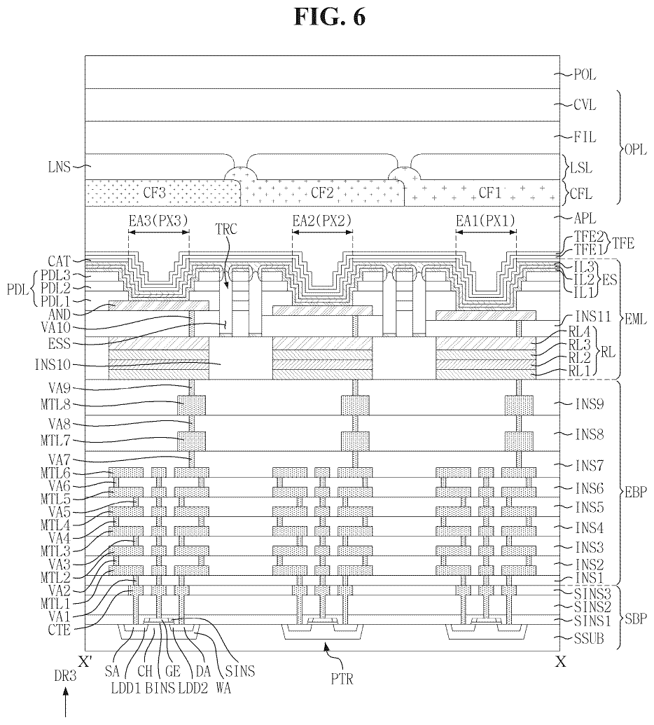

A plurality of unit pixels UPX include a plurality of pixels PX1, PX2, and PX3. The plurality of pixels PX1, PX2, and PX3 may include a plurality of pixel transistors as illustrated in FIG. 3, and the plurality of pixel transistors may be formed by a semiconductor process and located on a semiconductor substrate SSUB (see FIG. 6). For example, a plurality of pixel transistors of a data driver 700 may be formed as complementary metal oxide semiconductors (CMOSs).

Each of the plurality of pixels PX1, PX2, and PX3 may be connected to any one of the plurality of write scan lines GWL, any one of the plurality of control scan lines GCL, any one of the plurality of bias scan lines EBL, any one of the plurality of first emission control lines EL1, any one of the plurality of second emission control lines EL2, and any one of the plurality of data lines DL. Each of the plurality of pixels PX1, PX2, and PX3 may receive a data voltage of the data line DL according to a write scan signal of the write scan line GWL, and may allow a light-emitting element to emit light according to the data voltage.

The non-display area NDA includes a scan driver 610, an emission driver 620, and a data driver 700.

The scan driver 610 includes a plurality of scan transistors, and the emission driver 620 includes a plurality of light-emitting transistors. The plurality of scan transistors and the plurality of light-emitting transistors may be formed by a semiconductor process, and may be formed on a semiconductor substrate SSUB (see FIG. 6). For example, the plurality of scan transistors and the plurality of light-emitting transistors may be formed as CMOSs. It has been illustrated in FIG. 2 that the scan driver 610 is located on the left side of the display area DAA, and the emission driver 620 is located on the right side of the display area DAA, but the present disclosure is not limited thereto. For example, the scan drivers 610 and the emission drivers 620 may be located on both the left and right sides of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan-timing control signal SCS from the timing controller 400. The write scan signal output unit 611 may generate write scan signals according to the scan-timing control signal SCS of the timing controller 400, and may sequentially output the write scan signals to the write scan lines GWL. The control scan signal output unit 612 may generate control scan signals according to the scan-timing control signal SCS, and may sequentially output the control scan signals to the control scan lines GCL. The bias scan signal output unit 613 may generate bias scan signals according to the scan-timing control signal SCS, and may sequentially output the bias scan signals to the bias scan lines EBL.

The emission driver 620 includes a first emission control driver 621 and a second emission control driver 622. Each of the first emission control driver 621 and the second emission control driver 622 may receive an emission-timing control signal ECS from the timing controller 400. The first emission control driver 621 may generate first emission control signals according to the emission-timing control signal ECS, and may sequentially output the first emission control signals to the first emission control lines EL1. The second emission control driver 622 may generate second emission control signals according to the emission-timing control signal ECS, and may sequentially output the second emission control signals to the second emission control lines EL2.

The data driver 700 may include a plurality of data transistors, and the plurality of data transistors may be formed by a semiconductor process, and may be formed on a semiconductor substrate SSUB (see FIG. 6). For example, the plurality of data transistors may be formed as CMOSs.

The data driver 700 may receive digital video data DATA and a data-timing control signal DCS from the timing controller 400. The data driver 700 converts the digital video data DATA into analog data voltages according to the data-timing control signal DCS, and outputs the analog data voltages to the data lines DL. In this case, the pixels PX1, PX2, and PX3 may be selected by the write scan signals of the scan driver 610, and the data voltages may be supplied to the selected pixels PX1, PX2, and PX3.

The heat dissipation layer 200 may overlap the display panel 100 in a third direction DR3, which is a thickness direction of the display panel 100. The heat dissipation layer 200 may be located on one surface, for example, a rear surface, of the display panel 100. The heat dissipation layer 200 serves to dissipate heat generated from the display panel 100. The heat dissipation layer 200 may include a layer made of graphite or metal, such as silver (Ag), copper (Cu), or aluminum (Al) having high thermal conductivity.

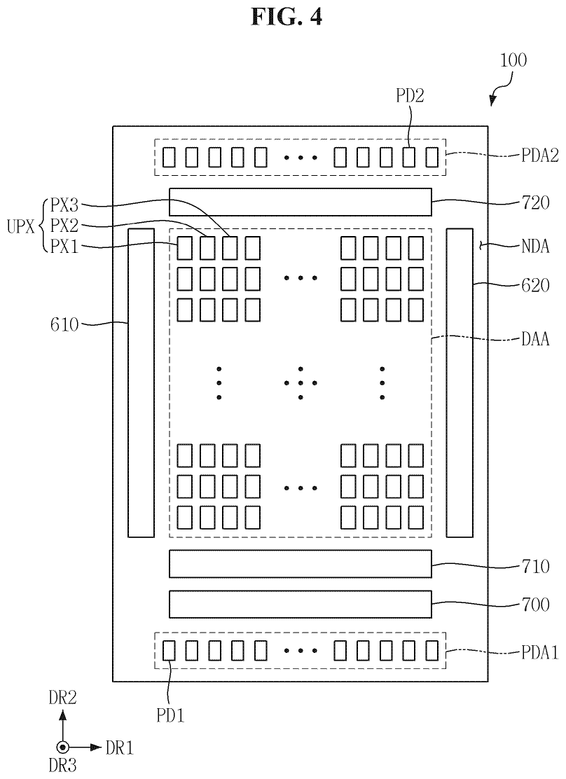

The circuit board 300 may be electrically connected to a plurality of first pads PD1 (see FIG. 4) of a first pad unit PDA1 (see FIG. 4) of the display panel 100 using a conductive adhesive member, such as an anisotropic conductive film. The circuit board 300 may be a flexible printed circuit board or a flexible film having a flexible material. It has been illustrated in FIG. 1 that the circuit board 300 is unbent, but the circuit board 300 may be bent. In this case, one end of the circuit board 300 may be located on the rear surface of the display panel 100 and/or a rear surface of the heat dissipation layer 200. One end of the circuit board 300 may be an end opposite to the other end of the circuit board 300 connected to the plurality of first pads PD1 (see FIG. 4) of the first pad unit PDA1 (see FIG. 4) of the display panel 100 using the conductive adhesive member.

The timing controller 400 may receive digital video data and timing signals from the outside. The timing controller 400 may generate the scan-timing control signal SCS, the emission-timing control signal ECS, and the data-timing control signal DCS for controlling the display panel 100 according to the timing signals. The timing controller 400 may output the scan-timing control signal SCS to the scan driver 610, and may output the emission-timing control signal ECS to the emission driver 620. The timing controller 400 may output the digital video data and the data-timing control signal DCS to the data driver 700.

The power supply unit 500 may generate a plurality of panel driving voltages according to an external source voltage. For example, the power supply unit 500 may generate a first driving voltage VSS, a second driving voltage VDD, and a third driving voltage VINT, and may supply the first driving voltage VSS, the second driving voltage VDD, and the third driving voltage VINT to the display panel 100. The first driving voltage VSS, the second driving voltage VDD, and the third driving voltage VINT will be described later with reference to FIG. 3.

Each of the timing controller 400 and the power supply unit 500 may be formed as an integrated circuit (IC), and may be attached to one surface of the circuit board 300. In this case, the scan-timing control signal SCS, the emission-timing control signal ECS, the digital video data DATA, and the data-timing control signal

DCS of the timing controller 400 may be supplied to the display panel 100 through the circuit board 300. In addition, the first driving voltage VSS, the second driving voltage VDD, and the third driving voltage VINT of the power supply unit 500 may be supplied to the display panel 100 through the circuit board 300.

Alternatively, each of the timing controller 400 and the power supply unit 500 may be located in the non-display area NDA of the display panel 100, similar to the scan driver 610, the emission driver 620, and the data driver 700. In this case, the timing controller 400 may include a plurality of timing transistors, and the power supply unit 500 may include a plurality of power transistors. The plurality of timing transistors and the plurality of power transistors may be formed by a semiconductor process, and may be formed on a semiconductor substrate SSUB (see FIG. 6). For example, the plurality of timing transistors and the plurality of power transistors may be formed as CMOSs. Each of the timing controller 400 and the power supply unit 500 may be located between the data driver 700 and the first pad unit PDA1 (see FIG. 4).

FIG. 3 is an equivalent circuit diagram of a first pixel according to one or more embodiments.

Referring to FIG. 3, a first pixel PX1 may be connected to a write scan line GWL, a control scan line GCL, a bias scan line EBL, a first emission control line EL1, a second emission control line EL2, and a data line DL. In addition, the first pixel PX1 may be connected to a first driving voltage line VSL to which a first driving voltage VSS corresponding to a low potential voltage is applied, a second driving voltage line VDL to which a second driving voltage VDD corresponding to a high potential voltage is applied, and a third driving voltage line VIL to which a third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be a voltage lower than the third driving voltage VINT. The second driving voltage VDD may be a voltage higher than the third driving voltage VINT.

The first pixel PX1 includes a plurality of transistors T1 to T6, a light-emitting element LE, a first capacitor CP1, and a second capacitor CP2.

The light-emitting element LE emits light according to a driving current flowing through a channel of a first transistor T1. An amount of light emitted from the light-emitting element LE may be proportional to the driving current Ids. The light-emitting element LE may be located between a fourth transistor T4 and the first driving voltage line VSL. A first electrode of the light-emitting element LE may be connected to a drain electrode of the fourth transistor T4, and a second electrode of the light-emitting element LE may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer located between the first electrode and the second electrode, but the present disclosure is not limited thereto. For example, the light-emitting element LE may be an inorganic light-emitting element including a first electrode, a second electrode, and an inorganic semiconductor located between the first electrode and the second electrode, and in this case, the light-emitting element LE may be a micro light-emitting diode.

The first transistor T1 may be a driving transistor controlling a source-drain current (hereinafter referred to as a “driving current”) flowing between a source electrode and a drain electrode according to a voltage applied to a gate electrode thereof. The first transistor T1 includes the gate electrode connected to a first node N1, the source electrode connected to a drain electrode of a sixth transistor T6, and the drain electrode connected to a second node N2.

A second transistor T2 may be located between one electrode of the first capacitor CP1 and the data line DL. The second transistor T2 is turned on by a write scan signal of the write scan line GWL to connect one electrode of the first capacitor CP1 to the data line DL. For this reason, a data voltage of the data line DL may be applied to one electrode of the first capacitor CP1. The second transistor T2 includes a gate electrode connected to the write scan line GWL, a source electrode connected to the data line DL, and a drain electrode connected to one electrode of the first capacitor CP1.

A third transistor T3 may be located between the first node N1 and the second node N2. The third transistor T3 is turned on by a control scan signal of the control scan line GCL to connect the first node N1 to the second node N2. For this reason, the gate electrode and the drain electrode of the first transistor T1 are connected to each other, and thus, the first transistor T1 may operate like a diode. The third transistor T3 includes a gate electrode connected to the control scan line GCL, a source electrode connected to the second node N2, and a drain electrode connected to the first node N1.

The fourth transistor T4 may be connected between the second node N2 and a third node N3. The fourth transistor T4 is turned on by a first emission control signal of the first emission control line EL1 to connect the second node N2 to the third node N3. For this reason, the driving current of the first transistor T1 may be supplied to the light-emitting element LE. The fourth transistor T4 includes a gate electrode connected to the first emission control line EL1, a source electrode connected to the second node N2, and the drain electrode connected to the third node N3.

A fifth transistor T5 may be located between the third node N3 and the third driving voltage line VIL. The fifth transistor T5 is turned on by a bias scan signal of the bias scan line EBL to connect the third node N3 to the third driving voltage line VIL. For this reason, the third driving voltage VINT of the third driving voltage line VIL may be applied to the first electrode of the light-emitting element LE. The fifth transistor T5 includes a gate electrode connected to the bias scan line EBL, a source electrode connected to the third node N3, and a drain electrode connected to the third driving voltage line VIL.

The sixth transistor T6 may be located between the source electrode of the first transistor T1 and the second driving voltage line VDL. The sixth transistor T6 is turned on by a second emission control signal of the second emission control line EL2 to connect the source electrode of the first transistor T1 to the second driving voltage line VDL. For this reason, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and the drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 includes one electrode connected to the gate electrode of the first transistor T1 and the other electrode connected to the second driving voltage line VDL.

The first node N1 is a contact point between the gate electrode of the first transistor T1, the drain electrode of the third transistor T3, the other electrode of the first capacitor CP1, and one electrode of the second capacitor CP2. The second node N2 is a contact point between the drain electrode of the first transistor T1, the source electrode of the third transistor T3, and the source electrode of the fourth transistor T4. The third node N3 is a contact point between the drain electrode of the fourth transistor T4, the source electrode of the fifth transistor T5, and the first electrode of the light-emitting element LE.

Each of the first to sixth transistors T1 to T6 may be a metal oxide semiconductor field effect transistor (MOSFET). For example, each of the first to sixth transistors T1 to T6 may be a P-type MOSFET, but the present disclosure is not limited thereto. Each of the first to sixth transistors T1 to T6 may be an N-type MOSFET. Alternatively, one or more of the first to sixth transistors T1 to T6 may be P-type MOSFETs, and one or more others of the first to sixth transistors T1 to T6 may be N-type MOSFETs.

It has been illustrated in FIG. 3 that the first pixel PX1 includes six transistors T1 to T6 and two capacitors C1 and C2, but it should be noted that an equivalent circuit diagram of the first pixel PX1 is not limited to that illustrated in FIG. 3. For example, the numbers of transistors and capacitors of the first pixel PX1 are not limited to those illustrated in FIG. 3.

In addition, an equivalent circuit diagram of a second pixel PX2 and an equivalent circuit diagram of a third pixel PX3 may be substantially the same as the equivalent circuit diagram of the first pixel PX1 described with reference to FIG. 3. Therefore, a description of the equivalent circuit diagram of the second pixel PX2 and the equivalent circuit diagram of the third pixel PX3 is omitted in the present disclosure.

FIG. 4 is a layout diagram illustrating an example of a display panel according to one or more embodiments.

Referring to FIG. 4, the display area DAA of the display panel 100 according to one or more embodiments includes a plurality of pixels PX arranged in a matrix form. The non-display area NDA of the display panel 100 according to one or more embodiments includes a scan driver 610, an emission driver 620, a data driver 700, a first distribution circuit 710, a second distribution circuit 720, a first pad unit PDA1, and a second pad unit PDA2.

The scan driver 610 may be located on a first side of the display area DAA, and the emission driver 620 may be located on a second side of the display area DAA. For example, the scan driver 610 may be located on one side of the display area DAA in the first direction DR1, and the emission driver 620 may be located on the other side of the display area DAA in the first direction DR1. That is, the scan driver 610 may be located on the left side of the display area DAA, and the emission driver 620 may be located on the right side of the display area DAA. However, the present disclosure is not limited thereto, and the scan drivers 610 and the emission drivers 620 may be located on both the first and second sides of the display area DAA.

The first pad unit PDA1 may include a plurality of first pads PD1 connected to pads or bumps of the circuit board 300 through a conductive adhesive member. The first pad unit PDA1 may be located on a third side of the display area DAA. For example, the first pad unit PDA1 may be located on one side of the display area DAA in the second direction DR2.

The first pad unit PDA1 may be located outside the data driver 700 in the second direction DR2. That is, the first pad unit PDA1 may be closer to an edge of the display panel 100 than the data driver 700 is.

The second pad unit PDA2 may include a plurality of second pads PD2 corresponding to inspection pads that inspect whether or not the display panel 100 operates normally. The plurality of second pads PD2 may be connected to a jig or a probe pin or connected to a circuit board for inspection in an inspection process. The circuit board for inspection may be a printed circuit board made of a rigid material or a flexible printed circuit board made of a flexible material.

The first distribution circuit 710 distributes data voltages applied through the first pad unit PDA1 to a plurality of data lines DL. For example, the first distribution circuit 710 may distribute data voltages applied through one first pad PD1 of the first pad unit PDA1 to P data lines DL (P is a positive integer of 2 or more), and for this reason, the number of first pads PD1 may be reduced. The first distribution circuit 710 may be located on the third side of the display area DAA of the display panel 100. For example, the first distribution circuit 710 may be located on one side of the display area DAA in the second direction DR2. That is, the first distribution circuit 710 may be located on the lower side of the display area DAA.

The second distribution circuit 720 distributes signals applied through the second pad unit PDA2 to the scan driver 610, the emission driver 620, and the data lines DL. The second pad unit PDA2 and the second distribution circuit 720 may be components for inspecting an operation of each of the pixels PX of the display area DAA. The second distribution circuit 720 may be located on a fourth side of the display area DAA of the display panel 100. For example, the second distribution circuit 720 may be located on the other side of the display area DAA in the second direction DR2. That is, the second distribution circuit 720 may be located on the upper side of the display area DAA.

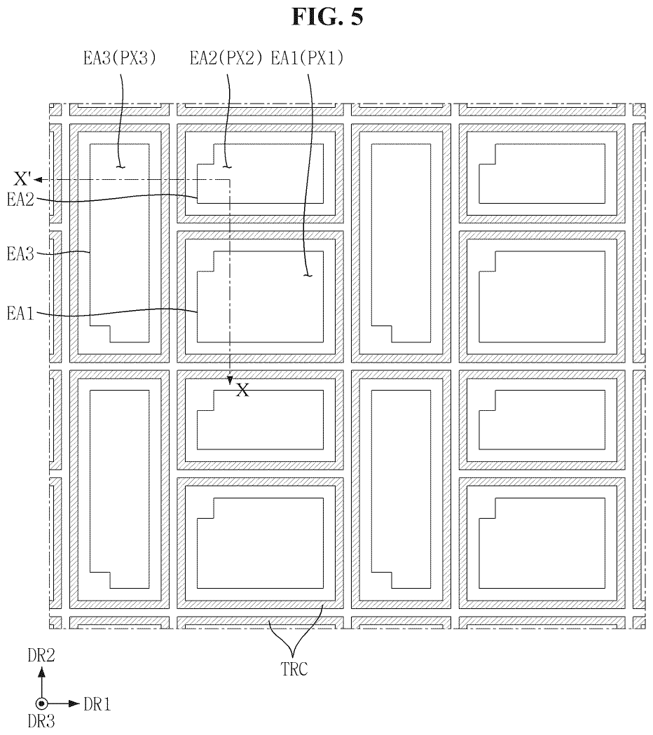

FIG. 5 is a layout diagram illustrating examples of a display area of FIG. 4.

Referring to FIG. 5, each of the plurality of unit pixels UPX includes a first emission area EA1 that is an emission area of the first pixel PX1, a second emission area EA2 that is an emission area of the second pixel PX2, and a third emission area EA3 that is an emission area of the third pixel PX3. In other words, the unit pixel UPX may include a unit emission area UEA, and this unit emission area UEA includes the above-described first emission area EA1, second emission area EA2, and third emission area EA3.

Referring to FIG. 5, each of the plurality of unit pixels UPX includes a first emission area EA1 that is an emission area of the first pixel PX1, a second emission area EA2 that is an emission area of the second pixel PX2, and a third emission area EA3 that is an emission area of the third pixel PX3.

Each of the first emission area EA1, the second emission area EA2, and the third emission area EA3 may have a polygonal shape, a circular shape, an elliptical shape, or an irregular shape in plan view, but the shape of each of the emission areas EA1 to EA3 are not limited thereto.

A maximum length of the third emission area EA3 in the first direction DR1 may be less than a maximum length of the first emission area EA1 in the first direction DR1 and a maximum length of the second emission area EA2 in the first direction DR1. The maximum length of the first emission area EA1 in the first direction DR1 and the maximum length of the second emission area EA2 in the first direction DR1 may be substantially the same as each other.

A maximum length of the third emission area EA3 in the second direction DR2 may be greater than a maximum length of the first emission area EA1 in the second direction DR2 and a maximum length of the second emission area EA2 in the second direction DR2. The maximum length of the first emission area EA1 in the second direction DR2 may be greater than the maximum length of the second emission area EA2 in the second direction DR2. The maximum length of the first emission area EA1 in the second direction DR2 may be less than the maximum length of the third emission area EA3 in the second direction DR2.

Each of the first emission area EA1, the second emission area EA2, and the third emission area EA3 may have a hexagonal shape including six straight lines, in plan view, as illustrated in FIG. 5, but the present disclosure is not limited thereto. Each of the first emission area EA1, the second emission area EA2, and the third emission area EA3 may have polygonal shapes other than the hexagonal shape, a circular shape, an elliptical shape, or an irregular shape in plan view.

As illustrated in FIG. 5, in each of the plurality of pixels PX, the second emission area EA2 and the third emission area EA3 may neighbor to each other in the first direction DR1. In addition, the first emission area EA1 and the third emission area EA3 may neighbor to each other in the first direction DR1. In addition, the first emission area EA1 and the second emission area EA2 may neighbor to each other in the second direction DR2. An area of the first emission area EA1, an area of the second emission area EA2, and an area of the third emission area EA3 may be different from each other.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may indicate that a main peak wavelength of the light is included in a wavelength band of approximately 380 nm to approximately 480 nm, the green wavelength band may indicate that a main peak wavelength of the light is included in a wavelength band of approximately 480 nm to approximately 560 nm, and the red wavelength band may indicate that a main peak wavelength of the light is included in a wavelength band of approximately 600 nm and approximately 750 nm.

It has been illustrated in FIGS. 5 and 6 that each of the plurality of unit pixels UPX includes three emission areas EA1, EA2, and EA3, but the present disclosure is not limited thereto. That is, each of the plurality of unit pixels UPX may also include four emission areas.

In addition, an arrangement of the emission areas of the plurality of unit pixels UPX is not limited to those illustrated in FIG. 5. For example, the emission areas of the plurality of unit pixels UPX may be located in a stripe structure in which the emission areas are arranged in the first direction DR1, a PenTile® structure (PenTile® being a registered trademark of Samsung Display Co., Ltd., Republic of Korea) in which the emission areas have a diamond arrangement, or a hexagonal structure in which emission areas having a hexagonal shape in plan view are arranged.

FIG. 6 is a cross-sectional view illustrating an example of the display panel taken along the line X-X′ of FIG. 5.

Referring to FIG. 6, the display panel 100 includes a semiconductor backplane SBP, a light-emitting element backplane EBP, a display element layer EML, an encapsulation layer TFE, and an optical layer OPL.

The semiconductor backplane SBP may include a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with first-type impurities. A plurality of well regions WA may be located in an upper surface of the semiconductor substrate SSUB. The plurality of well regions WA may be regions doped with second-type impurities. The second-type impurities may be different from the first-type impurities described above. For example, when the first-type impurities are p-type impurities, the second-type impurities may be n-type impurities. Alternatively, when the first-type impurities are n-type impurities, the second-type impurities may be p-type impurities.

Each of the plurality of well regions WA includes a source region SA corresponding to a source electrode of the pixel transistor PTR, a drain region DA corresponding to a drain electrode of the pixel transistor PTR, and a channel region CH located between the source region SA and the drain region DA.

A bottom insulating film BINS may be located between a gate electrode GE and the well region WA. Side surface insulating films SINS may be located on side surfaces of the gate electrode GE. The side surface insulating films SINS may be located on the bottom insulating film BINS.

Each of the source region SA and the drain region DA may be a region doped with the first-type impurities. The gate electrode GE of the pixel transistor PTR may overlap the well region WA in the third direction DR3. The channel region CH may overlap the gate electrode GE in the third direction DR3. The source region SA may be located on one side of the gate electrode GE, and the drain region DA may be located on the other side of the gate electrode GE (e.g., in plan view).

Each of the plurality of well regions WA further includes a first low-concentration impurity region LDD1 located between the channel region CH and the source region SA, and a second low-concentration impurity region LDD2 located between the channel region CH and the drain region DA. The first low-concentration impurity region LDD1 may be a region having a lower impurity concentration than the source region SA due to the bottom insulating film BINS. The second low-concentration impurity region LDD2 may be a region having a lower impurity concentration than the drain region DA due to the bottom insulating film BINS. A distance between the source region SA and the drain region DA may increase by the first low-concentration impurity region LDD1 and the second low-concentration impurity region LDD2. Therefore, a length of the channel region CH of each of the pixel transistors PTR may increase, and thus, the likelihood of punch-through and hot carrier phenomena caused by a short channel may be reduced or prevented.

A first semiconductor insulating film SINS1 may be located on the semiconductor substrate SSUB. The first semiconductor insulating film SINS1 may be formed as a silicon carbonitride (SiCN) or silicon oxide (SiOₓ)-based inorganic film, but the present disclosure is not limited thereto.

A second semiconductor insulating film SINS2 may be located on the first semiconductor insulating film SINS1. The second semiconductor insulating film SINS2 may be formed as a silicon oxide (SiOₓ)-based inorganic film, but the present disclosure is not limited thereto.

The plurality of contact terminals CTE may be located on the second semiconductor insulating film SINS2. The plurality of contact terminals CTE may be respectively connected to any one of the gate electrode GE, the source region SA, or the drain region DA of the pixel transistors PTR through a hole penetrating through the first semiconductor insulating film SINS1 and the second semiconductor insulating film INS2. Each of the plurality of contact terminals CTE may be made of any one of copper (Cu), aluminum (Al), tungsten (W), molybdenum (Mo), chromium (Cr), gold (Au), titanium (Ti), nickel (Ni), or neodymium (Nd), or alloys thereof.

A third semiconductor insulating film SINS3 may be located on side surfaces of each of the plurality of contact terminals CTE. An upper surface of each of the plurality of contact terminals CTE may be exposed without being covered by the third semiconductor insulating film SINS3. The third semiconductor insulating film SINS3 may be formed as a silicon oxide (SiOₓ)-based inorganic film, but the present disclosure is not limited thereto.

The semiconductor substrate SSUB may be replaced with a glass substrate or a polymer resin substrate, such as a polyimide substrate. In this case, thin film transistors may be located on the glass substrate or the polymer resin substrate. The glass substrate may be a rigid substrate that is not bent, and the polymer resin substrate may be a flexible substrate that may be bent or curved.

The light-emitting element backplane EBP includes a plurality of conductive layers MTL1 to MTL8, a plurality of vias VA1 to VA9, and a plurality of insulating films INS1 to INS9. In addition, the light-emitting element backplane EBP includes a plurality of insulating films INS1 to INS9 located between respective ones of the first to eighth conductive layers MTL1 to MTL8.

The first to eighth conductive layers MTL1 to MTL8 serve to implement a circuit of the first pixel PX1 illustrated in FIG. 4 by connecting the plurality of contact terminals CTE exposed from the semiconductor backplane SBP to each other. For example, only the first to sixth transistors T1 to T6 are formed in the semiconductor backplane SBP, and the connection between the first to sixth transistors T1 to T6 and the formation of the first capacitor CP1 and the second capacitor CP2 are performed through the first to eighth conductive layers MTL1 to MTL8. In addition, the connection between a drain region corresponding to the drain electrode of the fourth transistor T4, a source region corresponding to the source electrode of the fifth transistor T5, and the first electrode of the light-emitting element LE is also performed through the first to eighth conductive layers MTL1 to MTL8.

A first insulating film INS1 may be located on the semiconductor backplane SBP. Each of first vias VA1 may penetrate through the first insulating film INS1 to be connected to the contact terminal CTE exposed from the semiconductor backplane SBP. Each of the first conductive layers MTL1 may be located on the first insulating film INS1, and may be connected to the first via VA1.

A second insulating film INS2 may be located on the first insulating film INS1 and the first conductive layers MTL1. Each of second vias VA2 may penetrate through the second insulating film INS2 to be connected to the exposed first conductive layer MTL1. Each of the second conductive layers MTL2 may be located on the second insulating film INS2, and may be connected to the second via VA2.

A third insulating film INS3 may be located on the second insulating film INS2 and the second conductive layers MTL2. Each of third vias VA3 may penetrate through the third insulating film INS3 to be connected to the exposed second conductive layer MTL2. Each of the third conductive layers MTL3 may be located on the third insulating film INS3, and may be connected to the third via VA3.

A fourth insulating film INS4 may be located on the third insulating film INS3 and the third conductive layer MTL3. Each of fourth vias VA4 may penetrate through the fourth insulating film INS4 to be connected to the exposed third conductive layer MTL3. Each of the fourth conductive layers MTL4 may be located on the fourth insulating film INS4, and may be connected to the fourth via VA4.

A fifth insulating film INS5 may be located on the fourth insulating film INS4 and the fourth conductive layers MTL4. Each of fifth vias VA5 may penetrate through the fifth insulating film INS5 to be connected to the exposed fourth conductive layer MTL4. Each of the fifth conductive layers MTL5 may be located on the fifth insulating film INS5, and may be connected to the fifth via VA5.

A sixth insulating film INS6 may be located on the fifth insulating film INS5 and the fifth conductive layer MTL5. Each of sixth vias VA6 may penetrate through the sixth insulating film INS6 to be connected to the exposed fifth conductive layer MTL5. Each of the sixth conductive layers MTL6 may be located on the sixth insulating film INS6, and may be connected to the sixth via VA6.

A seventh insulating film INS7 may be located on the sixth insulating film INS6 and the sixth conductive layer MTL6. Each of seventh vias VA7 may penetrate through the seventh insulating film INS7 to be connected to the exposed sixth conductive layer MTL6. Each of the seventh conductive layers MTL7 may be located on the seventh insulating film INS7, and may be connected to the seventh via VA7.

An eighth insulating film INS8 may be located on the seventh insulating film INS7 and the seventh conductive layer MTL7. Each of eighth vias VA8 may penetrate through the eighth insulating film INS8 to be connected to the exposed seventh conductive layer MTL7. Each of the eighth conductive layers MTL8 may be located on the eighth insulating film INS8, and may be connected to the eighth via VA8.

The first to eighth conductive layers MTL1 to MTL8 and the first to eighth vias VA1 to VA8 may be made of substantially the same material. Each of the first to eighth conductive layers MTL1 to MTL8 and the first to eighth vias VA1 to VA8 may be made of any one of copper (Cu), aluminum (Al), tungsten (W), molybdenum (Mo), chromium (Cr), gold (Au), titanium (Ti), nickel (Ni), or neodymium (Nd), or alloys thereof. The first to eighth vias VA1 to VA8 may be made of substantially the same material. The first to eighth insulating films INS1 to INS8 may be formed as silicon oxide (SiOₓ)-based inorganic films, but the present disclosure is not limited thereto.

Each of a thickness of the first conductive layer MTL1, a thickness of the second conductive layer MTL2, a thickness of the third conductive layer MTL3, a thickness of the fourth conductive layer MTL4, a thickness of the fifth conductive layer MTL5, and a thickness of the sixth conductive layer MTL6 may be greater than each of a thickness of the first via VA1, a thickness of the second via VA2, a thickness of the third via VA3, a thickness of the fourth via VA4, a thickness of the fifth via VA5, and a thickness of the sixth via VA6. Each of the thickness of the second conductive layer MTL2, the thickness of the third conductive layer MTL3, the thickness of the fourth conductive layer MTL4, the thickness of the fifth conductive layer MTL5, and the thickness of the sixth conductive layer MTL6 may be greater than the thickness of the first conductive layer MTL1. The thickness of the second conductive layer MTL2, the thickness of the third conductive layer MTL3, the thickness of the fourth conductive layer MTL4, the thickness of the fifth conductive layer MTL5, and the thickness of the sixth conductive layer MTL6 may be substantially the same as each other. For example, the thickness of the first conductive layer MTL1 may be approximately 1360 Å, each of the thickness of the second conductive layer MTL2, the thickness of the third conductive layer MTL3, the thickness of the fourth conductive layer MTL4, the thickness of the fifth conductive layer MTL5, and the thickness of the sixth conductive layer MTL6 may be approximately 1440 Å, and each of the thickness of the first via VA1, the thickness of the second via VA2, the thickness of the third via VA3, the thickness of the fourth via VA4, the thickness of the fifth via VA5, and the thickness of the sixth via VA6 may be approximately 1150 Å.

Each of a thickness of the seventh conductive layer MTL7 and a thickness of the eighth conductive layer MTL8 may be greater than each of the thickness of the first conductive layer MTL1, the thickness of the second conductive layer MTL2, the thickness of the third conductive layer MTL3, the thickness of the fourth conductive layer MTL4, the thickness of the fifth conductive layer MTL5, and the thickness of the sixth conductive layer MTL6. Each of the thickness of the seventh conductive layer MTL7 and the eighth conductive layer MTL8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer MTL7 and the thickness of the eighth conductive layer MTL8 may be substantially the same as each other. For example, each of the thickness of the seventh conductive layer MTL7 and the thickness of the eighth conductive layer MTL8 may be approximately 9000 Å. Each of the thickness of the seventh via VA7 and the thickness of the eighth via VA8 may be approximately 6000 Å.

A ninth insulating film INS9 may be located on the eighth insulating film INS8 and the eighth conductive layer MTL8. The ninth insulating film INS9 may be formed as a silicon oxide (SiOₓ)-based inorganic film, but the present disclosure is not limited thereto.

Each of ninth vias VA9 may penetrate through the ninth insulating film INS9 to be connected to the exposed eighth conductive layer MTL8. Each of the ninth vias VA9 may be made of any one of copper (Cu), aluminum (Al), tungsten (W), molybdenum (Mo), chromium (Cr), gold (Au), titanium (Ti), nickel (Ni), or neodymium (Nd), or alloys thereof. A thickness of the ninth via VA9 may be approximately 16500 Å.

The display element layer EML may be located on the light-emitting element backplane EBP. The display element layer EML may include a reflective electrode layer RL, tenth and eleventh insulating films INS10 and INS11, tenth vias VA10, light-emitting elements LE each including a first electrode AND, a light-emitting stack ES, and a second electrode CAT, a pixel-defining film PDL, and a plurality of trenches TRC.

The reflective electrode layer RL may be located on the ninth insulating film INS9. The reflective electrode layer RL may include one or more reflective electrodes RL1, RL2, RL3, and RL4. For example, the reflective electrode layer RL may include first to fourth reflective electrodes RL1, RL2, RL3, and RL4 as illustrated in FIG. 6.

Each of the first reflective electrodes RL1 may be located on the ninth insulating film INS9, and may be connected to the ninth via VA9. Each of the first reflective electrodes RL1 may be made of any one of copper (Cu), aluminum (Al), tungsten (W), molybdenum (Mo), chromium (Cr), gold (Au), titanium (Ti), nickel (Ni), or neodymium (Nd), or alloys thereof. For example, each of the first reflective electrodes RL1 may include titanium nitride (TiN).

The second reflective electrodes RL2 may be located on a corresponding first reflective electrode RL1. Each of the second reflective electrodes RL2 may be made of any one of copper (Cu), aluminum (Al), tungsten (W), molybdenum (Mo), chromium (Cr), gold (Au), titanium (Ti), nickel (Ni), or neodymium (Nd), or alloys thereof. For example, each of the second reflective electrodes RL2 may include aluminum (Al).

The third reflective electrodes RL3 may be located on a corresponding second reflective electrode RL2. Each of the third reflective electrodes RL3 may be made of any one of copper (Cu), aluminum (Al), tungsten (W), molybdenum (Mo), chromium (Cr), gold (Au), titanium (Ti), nickel (Ni), or neodymium (Nd), or alloys thereof. For example, each of the third reflective electrodes RL3 may include titanium nitride (TiN).

The fourth reflective electrodes RL4 may be located on a corresponding third reflective electrode RL3. Each of the fourth reflective electrodes RL4 may be made of any one of copper (Cu), aluminum (Al), tungsten (W), molybdenum (Mo), chromium (Cr), gold (Au), titanium (Ti), nickel (Ni), or neodymium (Nd), or alloys thereof. For example, each of the fourth reflective electrodes RL4 may include titanium (Ti).

Because the second reflective electrodes RL2 are electrodes substantially reflecting light from the light-emitting elements LE, a thickness of the second reflective electrode RL2 may be greater than a thickness of the first reflective electrode RL1, a thickness of the third reflective electrode RL3, and a thickness of the fourth reflective electrode RL4. For example, each of the thickness of the first reflective electrode RL1, the third reflective electrode RL3, and the fourth reflective electrode RL4 may be approximately 100 Å, and the thickness of the second reflective electrode RL2 may be approximately 850 Å.

The tenth insulating film INS10 may be located on the ninth insulating film INS9. The tenth insulating film INS10 may be located between the reflective electrode layers RL adjacent to each other in a horizontal direction. The tenth insulating film INS10 may be located on the reflective electrode layer RL in the third pixel PX3. The tenth insulating film INS10 may be formed as a silicon oxide (SiOₓ)-based inorganic film, but the present disclosure is not limited thereto.

The eleventh insulating film INS11 may be located on the tenth insulating film INS10 and the reflective electrode layer RL. The eleventh insulating film INS11 may be formed as a silicon oxide (SiOₓ)-based inorganic film, but the present disclosure is not limited thereto. The tenth insulating film INS10 and the eleventh insulating film INS11 may be optical auxiliary layers through which light reflected by the reflective electrode layer RL among light emitted from the light-emitting elements LE passes.

In one or more embodiments, to adjust a resonance distance of the light emitted from the light-emitting elements LE in at least one of the first pixel PX1, the second pixel PX2, and the third pixel PX3, the tenth insulating film INS10 and the eleventh insulating film INS11 may not be located below the first electrode AND of the first pixel PX1. The first electrode AND of the first pixel PX1 may be directly located on the reflective electrode layer RL. The eleventh insulating film INS11 may be located below the first electrode AND of the second pixel PX2. In one or more embodiments, the tenth insulating film INS10 and the eleventh insulating film INS11 may be located below the first electrode AND of the third pixel PX3.

In summary, a distance between the first electrode AND and the reflective electrode layer RL may be different in each of the first pixel PX1, the second pixel PX2, and the third pixel PX3. That is, to adjust a distance from the reflective electrode layer RL to the second electrode CAT according to a main wavelength of light emitted from each of the first pixel PX1, the second pixel PX2, and the third pixel PX3, the presence or absence of the tenth insulating film INS10 and/or the eleventh insulating film INS11 may be set in each of the first pixel PX1, the second pixel PX2, and the third pixel PX3. For example, it has been illustrated in FIG. 6 that a distance between the first electrode AND and the reflective electrode layer RL in the third pixel PX3 is greater than a distance between the first electrode AND and the reflective electrode layer RL in the second pixel PX2, and a distance between the first electrode AND and the reflective electrode layer RL in the first pixel PX1. Also, the distance between the first electrode AND and the reflective electrode layer RL in the second pixel PX2 is greater than the distance between the first electrode AND and the reflective electrode layer RL in the first pixel PX1, but the present disclosure is not limited thereto.

In addition, the tenth insulating film INS10 and the eleventh insulating film INS11 have been illustrated in one or more embodiments of the present disclosure, but a twelfth insulating film located below the first electrode AND of the first pixel PX1 may be added. In this case, the eleventh insulating film INS11 and the twelfth insulating film INS12 may be located below the first electrode AND of the second pixel PX2, and the tenth insulating film INS10, the eleventh insulating film INS11, and the twelfth insulating film INS12 may be located below the first electrode AND of the third pixel PX3, in one or more embodiments.

Each of the tenth vias VA10 may penetrate through the tenth insulating film INS10 and/or the eleventh insulating film INS11 in the second pixel PX2 and the third pixel PX3 to be connected to the exposed fourth reflective electrode RL4. Each of the tenth vias VA10 may be made of any one of copper (Cu), aluminum (Al), tungsten (W), molybdenum (Mo), chromium (Cr), gold (Au), titanium (Ti), nickel (Ni), or neodymium (Nd), or alloys thereof. A thickness of the tenth via VA10 in the second pixel PX2 may be less than a thickness of the tenth via VA10 in the third pixel PX3.

The first electrode AND of each of the light-emitting elements LE may be located on the tenth insulating film INS10, and may be connected to the tenth via VA10. The first electrode AND of each of the light-emitting elements LE may be connected to the drain region DA or the source region SA of the pixel transistor PTR through the tenth via VA10, the first to fourth reflective electrodes RL1 to RL4, the first to ninth vias VA1 to VA9, the first to eighth conductive layers MTL1 to MTL8, and the contact terminal CTE. The first electrode AND of each of the light-emitting elements LE may be made of any one of copper (Cu), aluminum (Al), tungsten (W), molybdenum (Mo), chromium (Cr), gold (Au), titanium (Ti), nickel (Ni), or neodymium (Nd), or alloys thereof. For example, the first electrode AND of each of the light-emitting elements LE may be made of titanium nitride (TiN).

The pixel-defining film PDL may be located on a partial area of the first electrode AND of each of the light-emitting elements LE. The pixel-defining film PDL may cover an edge of the first electrode AND of each of the light-emitting elements LE. The pixel-defining film PDL serves to partition the first emission areas EA1, the second emission areas EA2, and the third emission areas EA3.

The first emission area EA1 may be defined as an area where the first electrode AND, the light-emitting stack ES, and the second electrode CAT are sequentially stacked in the first pixel PX1 to emit light. The second emission area EA2 may be defined as an area where the first electrode AND, the light-emitting stack ES, and the second electrode CAT are sequentially stacked in the second pixel PX2 to emit light. The third emission area EA3 may be defined as an area where the first electrode AND, the light-emitting stack ES, and the second electrode CAT are sequentially stacked in the third pixel PX3 to emit light.

The pixel-defining film PDL may include first to third pixel-defining films PDL1, PDL2, and PDL3. The first pixel-defining film PDL1 may be located on the edge of the first electrode AND of each of the light-emitting elements LE, the second pixel-defining film PDL2 may be located on the first pixel-defining film PDL1, and the third pixel-defining film PDL3 may be located on the second pixel-defining film PDL2. The first pixel-defining film PDL1, the second pixel-defining film PDL2, and the third pixel-defining film PDL3 may be formed as silicon oxide (SiOₓ)-based inorganic films, but the present disclosure is not limited thereto. Each of a thickness of the first pixel-defining film PDL1, a thickness of the second pixel-defining film PDL2, and a thickness of the third pixel-defining film PDL3 may be approximately 500 Å.

When the first pixel-defining film PDL1, the second pixel-defining film PDL2, and the third pixel-defining film PDL3 are formed as one pixel-defining film, a height of the one pixel-defining film increases, such that a first encapsulation inorganic film TFE1 may be disconnected due to step coverage. The step coverage refers to a ratio of a degree at which a thin film is coated on an inclined portion to a degree at which a thin film is coated on a flat portion. The lower the step coverage, the more likely it is that the thin film will be disconnected at the inclined portion.

Therefore, to reduce or prevent the likelihood of the first encapsulation inorganic film TFE1 being disconnected due to the step coverage, the first pixel-defining film PDL1, the second pixel-defining film PDL2, and the third pixel-defining film PDL3 may have a cross-sectional structure with a step having a staircase shape. For example, a width of the first pixel-defining film PDL1 may be greater than a width of the second pixel-defining film PDL2 and a width of the third pixel-defining film PDL3. Also, the width of the second pixel-defining film PDL2 may be greater than the width of the third pixel-defining film PDL3. The width of the first pixel-defining film PDL1 refers to a length of the first pixel-defining film PDL1 in a horizontal direction defined by the first direction DR1 and/or the second direction DR2.

Each of the plurality of trenches TRC may penetrate through the first pixel-defining film PDL1, the second pixel-defining film PDL2, and the third pixel-defining film PDL3. In addition, each of the plurality of trenches TRC may penetrate through the eleventh insulating film INS11. In each of the plurality of trenches TRC, the tenth insulating film INS10 may have a shape in which a portion thereof is trenched.

At least one trench TRC may be located between the pixels PX1, PX2, and PX3 neighboring to each other. It has been illustrated in FIG. 6 that two trenches TRC are located between the pixels PX1, PX2, and PX3 neighboring to each other, but the present disclosure is not limited thereto.

The light-emitting stack ES may include a plurality of intermediate layers. It has been illustrated in FIG. 6 that the light-emitting stack ES has a three-tandem structure including a first stack layer IL1, a second stack layer IL2, and a third stack layer IL3, but the present disclosure is not limited thereto. For example, the light-emitting stack ES may have a two-tandem structure including two intermediate layers.

In the three-tandem structure, the light-emitting stack ES may have a tandem structure including a plurality of stack layers IL1, IL2, and IL3 for emitting different light. For example, the light-emitting stack ES may include a first stack layer IL1 emitting light of a first color, a second stack layer IL2 emitting light of a second color, and a third stack layer IL3 emitting light of a third color. The first stack layer IL1, the second stack layer IL2, and the third stack layer IL3 may be sequentially stacked.

The first stack layer IL1 may have a structure in which a first hole-transporting layer, a first organic light-emitting layer for emitting the light of the first color, and a first electron-transporting layer are sequentially stacked. The second stack layer IL2 may have a structure in which a second hole-transporting layer, a second organic light-emitting layer for emitting the light of the second color, and a second electron-transporting layer are sequentially stacked. The third stack layer IL3 may have a structure in which a third hole-transporting layer, a third organic light-emitting layer for emitting the light of the third color, and a third electron-transporting layer are sequentially stacked. In this case, the light-emitting stack ES may emit white light mixed in which the light of the first color (e.g., red light) from the first organic light-emitting layer, the light of the second color (e.g., green light) from the second organic light-emitting layer, and the light of the third color (e.g., blue light) from the third organic light-emitting layer are mixed. Accordingly, the white light may be provided from the first emission area EA1, the second emission area EA2, and the third emission area EA3. Here, the white light that passed through the first emission area EA1 may be incident on a first color filter CF1, the white light that passed through the second emission area EA2 may be incident on a second color filter CF2, and the white light that passed through the third emission area EA3 may be incident on a third color filter CF3.

A first charge generation layer for supplying charges to the second stack layer IL2 and for supplying electrons to the first stack layer IL1 may be located between the first stack layer IL1 and the second stack layer IL2. The first charge generation layer may include an N-type charge generation layer supplying electrons to the first stack layer IL1 and a P-type charge generation layer supplying holes to the second stack layer IL2. The N-type charge generation layer may include a dopant of a metal material.

A second charge generation layer for supplying charges to the third stack layer IL3 and for supplying electrons to the second stack layer IL2 may be located between the second stack layer IL2 and the third stack layer IL3. The second charge generation layer may include an N-type charge generation layer supplying electrons to the second stack layer IL2 and a P-type charge generation layer supplying holes to the third stack layer IL3.

The first stack layer IL1 may be located on the first electrodes AND and the pixel-defining film PDL, and may be located on a bottom surface of each of the trenches TRC. Due to the trenches TRC, the first stack layer IL1 may be disconnected between the pixels PX1, PX2, and PX3 neighboring to each other. The second stack layer IL2 may be located on the first stack layer IL1. Due to the trenches TRC, the second stack layer IL2 may be disconnected between the pixels PX1, PX2, and PX3 neighboring to each other. A cavity ESS or an empty space may be located between the first stack layer IL1 and the second stack layer IL2. The third stack layer IL3 may be located on the second stack layer IL2. The third stack layer IL3 may not be disconnected by the trenches TRC, and may be located to cover the second stack layer IL2 in each of the trenches TRC. For example, in the three-tandem structure, each of the plurality of trenches TRC may be a structure for disconnecting the first and second stack layers IL1 and IL2, the first charge generation layer, and the second charge generation layer of the display element layer EML between the pixels PX1, PX2, and PX3 neighboring to each other. In addition, in the two-tandem structure, each of the plurality of trenches TRC may be a structure for disconnecting a charge generation layer located between a lower intermediate layer and an upper intermediate layer.

To stably disconnect the first and second stack layers IL1 and IL2 of the display element layer EML between the pixels PX1, PX2, and PX3 neighboring to each other, a height of each of the plurality of trenches TRC may be greater than a height of the pixel-defining film PDL. The height of each of the plurality of trenches TRC refers to a length of each of the plurality of trenches TRC in the third direction DR3. The height of the pixel-defining film PDL refers to a length of the pixel-defining film PDL in the third direction DR3. To disconnect the first and second intermediate layers IL1 and IL2 of the display element layer EML between the pixels PX1, PX2, and PX3 neighboring to each other, other structures may exist instead of the trenches TRC. For example, instead of the trenches TRC, partition walls having a reverse tapered shape may be located on the pixel-defining film PDL.

The number of stack layers IL1, IL2, and IL3 emitting the different light is not limited to that illustrated in FIG. 6. For example, the light-emitting stack ES may include two intermediate layers. In this case, any one of the two intermediate layers may be substantially the same as the first stack layer IL1, and the other of the two intermediate layers may include a second hole-transporting layer, a second organic light-emitting layer, a third organic light-emitting layer, and/or a second electron-transporting layer. In this case, a charge generation layer for supplying electrons to any one intermediate layer and for supplying charges to the other intermediate layer may be located between the two intermediate layers.

It has been illustrated in FIG. 6 that the first to third stack layers IL1, IL2, and IL3 are all located in the first emission area EA1, the second emission area EA2, and the third emission area EA3, but the present disclosure is not limited thereto. For example, the first stack layer IL1 may be located in the first emission area EA1, and may not be located in the second emission area EA2 and the third emission area EA3. In addition, the second stack layer IL2 may be located in the second emission area EA2, and may be omitted from the first emission area EA1 and the third emission area EA3. In addition, the third stack layer IL3 may be located in the third emission area EA3, and may be omitted from the first emission area EA1 and the second emission area EA2. In this case, first to third color filters CF1, CF2, and CF3 of the optical layer OPL may be omitted.

The second electrode CAT may be located on the third stack layer IL3. The second electrode CAT may be located on the third stack layer IL3 in each of the plurality of trenches TRC. The second electrode CAT may be made of a transparent conductive material (TCO), such as indium tin oxide (ITO) or indium zinc oxide (IZO) capable of transmitting light therethrough or a semi-transmissive conductive material, such as magnesium (Mg), silver (Ag), or an alloy of magnesium (Mg) and silver (Ag). When the second electrode CAT is made of the semi-transmissive conductive material, light emission efficiency of each of the first to third pixels PX1, PX2, and PX3 may be increased by a micro cavity.

The encapsulation layer TFE may be located on the display element layer EML. The encapsulation layer TFE may include at least one inorganic film TFE1 or TFE2 to reduce or prevent oxygen or moisture permeating into the display element layer EML. For example, the encapsulation layer TFE may include a first encapsulation inorganic film TFE1 and a second encapsulation inorganic film TFE2.

The first encapsulation inorganic film TFE1 may be located on the second electrode CAT. The first encapsulation inorganic film TFE1 may be formed as multiple films in which one or more inorganic films of a silicon nitride (SiNₓ) layer, a silicon oxynitride (SiON) layer, and a silicon oxide (SiOₓ) layer are alternately stacked. The first encapsulation inorganic film TFE1 may be formed by a chemical vapor deposition (CVD) process.

The second encapsulation inorganic film TFE2 may be located on the first encapsulation inorganic film TFE1. The second encapsulation inorganic film TFE2 may be formed as a titanium oxide (TiOₓ) layer or an aluminum oxide (AlOₓ) layer, but the present disclosure is not limited thereto. The second encapsulation inorganic film TFE2 may be formed by an atomic layer deposition (ALD) process. A thickness of the second encapsulation inorganic film TFE2 may be less than a thickness of the first encapsulation inorganic film TFE1.

An organic film APL may be a layer for increasing interfacial adhesive strength between the encapsulation layer TFE and the optical layer OPL. The organic film APL may be an organic film made of an acrylic resin, an epoxy resin, a phenolic resin, a polyamide resin, a polyimide resin, or the like.

The optical layer OPL includes a color filter layer CFL, a lens layer LSL, a filling layer FIL, a cover layer CVL, and a polarizing layer POL.

The color filter layer CFL may include a plurality of color filters CF1, CF2, and CF3. The plurality of color filters CF1, CF2, and CF3 may include first to third color filters CF1, CF2, and CF3. The first to third color filters CF1, CF2, and CF3 may be located on an adhesive layer ADL.

The first color filter CF1 may overlap the first emission area EA1 of the first pixel PX1. The first color filter CF1 may transmit the light of the first color, for example, light of a red wavelength band, therethrough. The red wavelength band may be approximately 600 nm to approximately 750 nm. Therefore, the first color filter CF1 may transmit the light of the first color among light emitted from the first emission area EA1 therethrough.

The second color filter CF2 may overlap the second emission area EA2 of the second pixel PX2. The second color filter CF2 may transmit the light of the second color, for example, light of a green wavelength band, therethrough. The green wavelength band may be approximately 480 nm to approximately 560 nm. Therefore, the second color filter CF2 may transmit the light of the second color among light emitted from the second emission area EA2 therethrough.

The third color filter CF3 may overlap the third emission area EA3 of the third pixel PX3. The third color filter CF3 may transmit the light of the third color, for example, light of a blue wavelength band, therethrough. The blue wavelength band may be approximately 370 nm to approximately 460 nm. Therefore, the third color filter CF3 may transmit the light of the third color among light emitted from the third emission area EA3 therethrough.

The lens layer LSL may be located on the color filter layer CFL. The lens layer LSL may include a plurality of lenses LNS. Each of the plurality of lenses LNS may be located on each of the first color filter CF1, the second color filter CF2, and the third color filter CF3. Each of the plurality of lenses LNS may be a structure for increasing a ratio of light directed to a front surface of the display device 10. Each of the plurality of lenses LNS may have a cross-sectional shape convex in an upward direction.

The filling layer FIL may be located on the lens layer LSL. For example, the filling layer FIL may be located on the plurality of lenses LNS. The filling layer FIL may have a refractive index (e.g., predetermined refractive index) so that light travels in the third direction DR3 at an interface between the plurality of lenses LNS and the filling layer FIL. In addition, the filling layer FIL may be a planarizing layer. The filling layer

FIL may be an organic film made of an acrylic resin, an epoxy resin, a phenolic resin, a polyamide resin, a polyimide resin, or the like.

The cover layer CVL may be located on the filling layer FIL. The cover layer CVL may be a glass substrate or a polymer resin, such as a resin. When the cover layer CVL is the glass substrate, the cover layer CVL may be attached onto the filling layer FIL. In this case, the filling layer FIL may serve to adhere the cover layer CVL. When the cover layer CVL is the glass substrate, the cover layer CVL may serve as an encapsulation substrate. When the cover layer CVL is the polymer resin, such as the resin, the cover layer CVL may be directly applied onto the filling layer FIL.

The polarizing layer POL may be located on the cover layer CVL. The polarizing layer POL may be a structure for reducing or preventing deterioration in visibility due to external light reflection. The polarizing layer POL may include a linear polarizing plate and a phase retardation film. For example, the phase retardation film may be a λ/4 plate (quarter-wave plate), but the present disclosure is not limited thereto. However, when visibility due to external light reflection is sufficiently improved by the first to third color filters CF1, CF2, and CF3, the polarizing layer POL may be omitted.

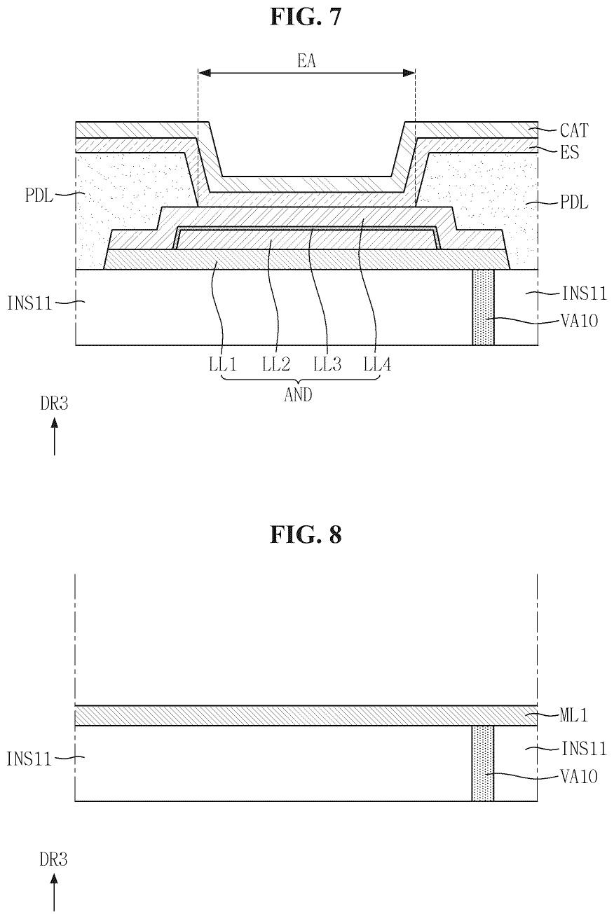

FIG. 7 is a cross-sectional view of a display device according to one or more embodiments.

The display device 10 according to one or more embodiments may include an anode electrode AND, a pixel-defining film PDL, an emission stack ES, and a cathode electrode CAT.

The anode electrode AND may include a first layer LL1, a second layer LL2, a third layer LL3, and a fourth layer LL4.

The first layer LL1 may be located on the eleventh insulating film INS11. The first layer LL1 may be connected to the tenth via VA10 on the eleventh insulating film INS11. For example, the first layer LL1 may be connected to the tenth via VA10 inside a via hole penetrating the eleventh insulating film INS11. The first layer LL1 may be made of any one of copper (Cu), aluminum (Al), tungsten (W), molybdenum (Mo), chromium (Cr), gold (Au), titanium (Ti), nickel (Ni), or neodymium (Nd), or alloys thereof. For example, the first layer LL1 may be made of titanium (Ti). The thickness of the first layer LL1 may be about 200 Å or less. Meanwhile, in plan view, the first layer LL1 may have a bigger area than the second layer LL2. Here, the thickness may mean the size in a third direction DR3, and the area may mean the size in a first direction DR1 and a second direction DR2.

The second layer LL2 may be located on the first layer LL1. For example, the second layer LL2 may be located at the central portion of the upper surface of the first layer LL1. The second layer LL2 may be located between the first layer LL1 and the third layer LL3 to be described later. For example, the second layer LL2 may be surrounded by the first layer LL1 and the third layer LL3. The second layer LL2 may be in contact with the first layer LL1 on the first layer LL1. The second layer LL2 may be made of any one of copper (Cu), aluminum (Al), tungsten (W), molybdenum (Mo), chromium (Cr), gold (Au), titanium (Ti), nickel (Ni), or neodymium (Nd), or alloys thereof. For example, the second layer LL2 may contain aluminum (Al). The thickness of the second layer LL2 may be about 200 Å or more, and the width of the second layer LL2 may be about 3 μm or less. Here, the thickness may mean the size in the third direction DR3, and the width may mean the size in the first direction DR1 or the second direction DR2.

The third layer LL3 may be located on the upper surface and the side surfaces of the second layer LL2. The third layer LL3 may be located between the second layer LL2 and the fourth layer LL4 to be described later. The third layer LL3 may contain an oxide (e.g., aluminum oxide). For example, the third layer LL3 may be an oxide layer formed on the surface of the second layer LL2, and may contain aluminum oxide (AlOₓ). The third layer LL3 may have a thickness of about 30 Å or more. Here, the thickness may mean the size in the third direction DR3.

The fourth layer LL4 may be located on the upper surface and the side surfaces of the third layer LL3. One end of the fourth layer LL4 may be located to correspond to one end of the first layer LL1, and the other end of the fourth layer LL4 may be located to correspond to the other end of the first layer LL1. Accordingly, in plan view, the edge of the fourth layer LL4 may overlap the edge of the first layer LL1. The fourth layer LL4 may be connected to the first layer LL1. For example, the fourth layer LL4 may be directly connected to the first layer LL1. In other words, the fourth layer LL4 may be directly connected (or clad) to the edge of the upper surface of the first layer LL1. The fourth layer LL4 may be made of a transparent conductive material (TCO), such as indium tin oxide (ITO) and indium zinc oxide (IZO) or a semi-transparent conductive material, such as magnesium (Mg), silver (Ag), or an alloy of magnesium (Mg) and silver (Ag). For example, the fourth layer LL4 may include ITO. The thickness of the fourth layer LL4 may be about 300 Å or less. Meanwhile, in plan view, the fourth layer LL4 may have a bigger area than the second layer LL2. Here, the thickness may mean the size in the third direction DR3, and the area may mean the size in the first direction DR1 by the size in the second direction DR2. Meanwhile, the length of the interface between the fourth layer LL4 and the first layer LL1 may be about 38 nm or more. For example, in FIG. 7, the length of the interface between the left side of the fourth layer LL4 and the left side of the first layer LL1 may be about 38 nm or more, and the length of the interface between the right side of the fourth layer LL4 and the right side of the first layer LL1 may be about 38 nm.

The pixel-defining film PDL may define the emission area EA of the pixel. The pixel-defining film PDL may be located on the edge of the upper surface and the side surface of the fourth layer LL4. In addition, the pixel-defining film PDL may be further located on the side surface of the first layer LL1. The emission area EA may overlap the second layer LL2 of the anode electrode AND. For example, in plan view, the emission area EA may be surrounded by the edge of the second layer LL2. Meanwhile, like the pixel-defining film PDL of FIG. 6 described above, the pixel-defining film PDL may include a first pixel-defining film PDL1, a second pixel-defining film PDL2, and a third pixel-defining film PDL3.

The light-emitting stack ES may be located on the anode electrode AND and the pixel-defining film PDL. Like the light-emitting stack ES of FIG. 6 described above, the light-emitting stack ES may have a three tandem structure including a first stack layer IL1, a second stack layer IL2, and a third stack layer IL3.

The cathode electrode CAT may be located on the light-emitting stack ES. The cathode electrode CAT may be made of a transparent conductive material (TCO), such as indium tin oxide (ITO) and/or indium zinc oxide (IZO) capable of transmitting light or a semi-transparent conductive material, such as magnesium (Mg), silver (Ag), or an alloy of magnesium (Mg) and silver (Ag).

Meanwhile, the semiconductor backplane SBP, the light-emitting element backplane EBP, the reflective electrode layer RL, and the tenth insulating films INS10 of FIG. 6 may be located below the eleventh insulating film INS11. In addition, the encapsulation layer TFE, the organic film APL, and the optical layer OPL may be located on the cathode electrode CAT of FIG. 7.

According to one or more embodiments, the first layer LL1 (e.g., aluminum layer) and the fourth layer LL4 (e.g., ITO layer) of the anode electrode AND may be in direct contact with each other. Accordingly, the anode electrode AND according to one or more embodiments may contain aluminum, but may not require TiN layer to reduce or prevent oxidation of the aluminum. The oxide layer of the surface of the aluminum layer shields electrical connection of the aluminum layer and the titanium layer, and to solve such problem, an additional metal layer (e.g., TiN layer) may be required between the aluminum layer and the titanium layer. However, the display device 10 according to one or more embodiments does not require such additional metal layer. Accordingly, the display device 10 according to one or more embodiments may have high transmittance (for example, high transmittance due to omission of TiN layer) as well as excellent reflectivity (for example, excellent reflectivity due to aluminum layer). Accordingly, the display device 10 according to one or more embodiments may provide light of high luminance even with low power.

FIGS. 8 to 17 are cross-sectional views of a process illustrating a method of manufacturing a display device according to one or more embodiments.

After the tenth via VA10 and the eleventh insulating film INS11 are formed on the semiconductor substrate SSUB, a first material layer ML1 may be located on the eleventh insulating film INS11, as shown in FIG. 8. For example, the first material layer ML1 may be deposited on the entire surface of the semiconductor substrate SSUB including the eleventh insulating film INS11. The first material layer ML1 may contain titanium.

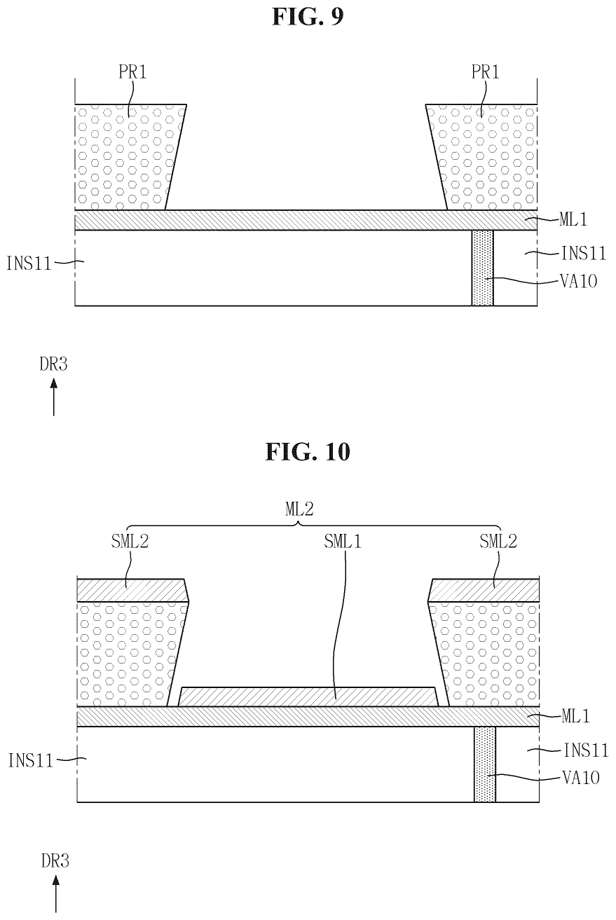

Subsequently, as illustrated in FIG. 9, a first photoresist pattern PR1 may be located on the first material layer ML1. The first photoresist pattern PR1 may have a reverse tapered shape. For example, the first photoresist pattern PR1 may have a width that gradually increases along the third direction DR3. The first photoresist pattern PR1 may be formed as a negative photoresist. For example, the first photoresist pattern PR1 may be formed as a lift-off photoresist.

Next, as illustrated in FIG. 10, a second material layer ML2 may be located on the first material layer ML1 and the first photoresist pattern PR1. For example, the second material layer ML2 may be deposited on the entire surface of the semiconductor substrate SSUB including the first material layer ML1 and the first photoresist pattern PR1. The second material layer ML2 may contain aluminum (Al). At this time, the second material layer ML2 may be separated into a plurality of parts by the first photoresist pattern PR1 of a reverse tapered shape. For example, the second material layer ML2 may include a first sub-material layer SML1 and a second sub-material layer SML2 separated from each other by the first photoresist pattern PR1. The first sub-material layer SML1 may be located on the first material layer ML1, and the second sub-material layer SML2 may be located on the first photoresist pattern PR1.

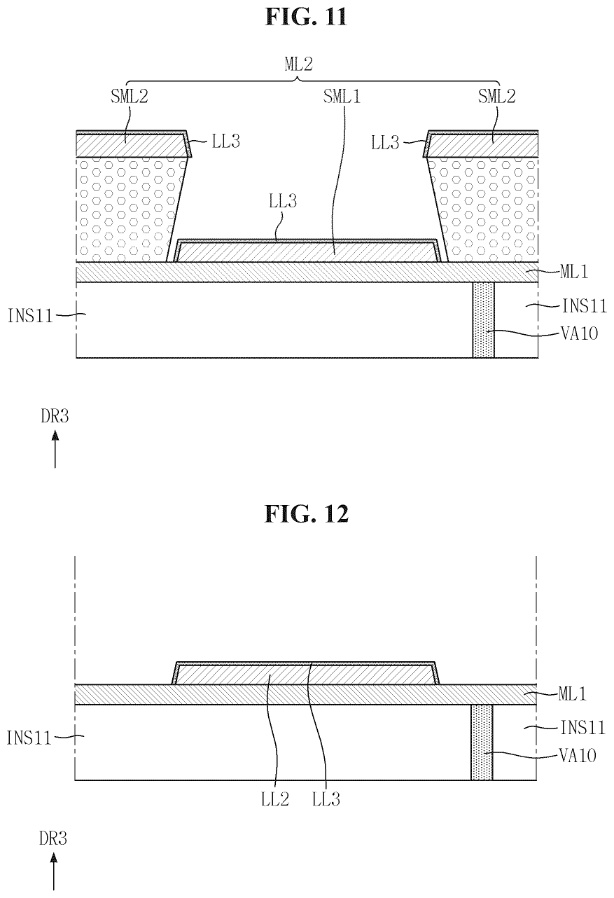

Thereafter, as illustrated in FIG. 11, as the second material layer ML2 is left during a time (e.g., predetermined time), a third layer LL3 (e.g., oxide layer) may be formed on the surface of the second material layer ML2. For example, the third layer LL3 (e.g., oxide layer) may be formed on each of the surface of the first sub-material layer SML1 and the surface of the second sub-material layer SML2. The third layer LL3 may contain aluminum oxide.

Next, as illustrated in FIG. 12, the first photoresist pattern PR1 may be removed. At this time, as the first photoresist pattern PR1 is removed, the second sub-material layer SML2 and the third layer LL3 on the first photoresist pattern PR1 may be removed along with the first photoresist pattern PR1. As the second sub-material layer SML2 of the second material layer ML2 is removed, a second layer LL2 may be formed on the first material layer ML1. In other words, after the first photoresist pattern PR1 and the second sub-material layer SML2 are removed, the first sub-material layer SML1 remaining on the first material layer ML1 may serve as the second layer LL2. The first photoresist pattern PR1 may be removed by a stripper.

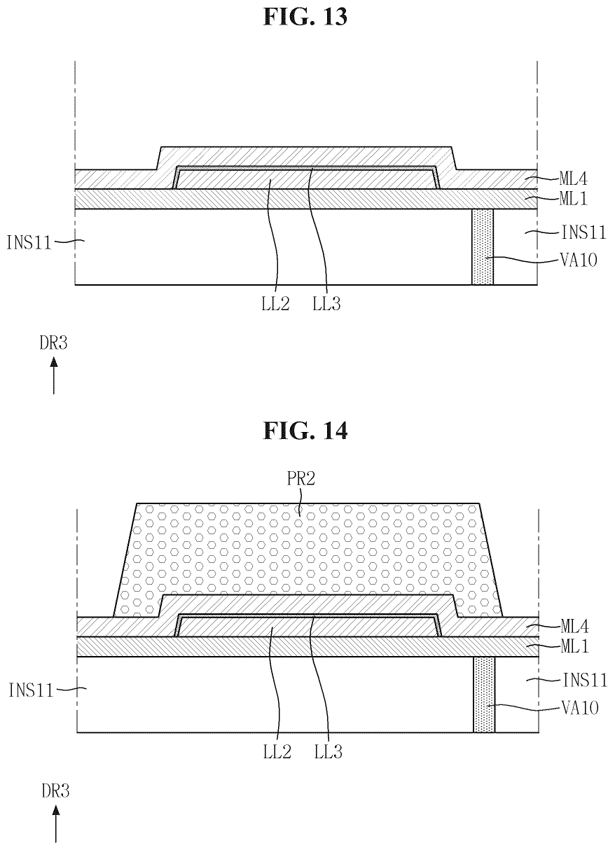

Subsequently, as illustrated in FIG. 13, a fourth material layer ML4 may be located on the third layer LL3. The fourth material layer ML4 may be deposited on the entire surface of the semiconductor substrate SSUB including the third layer LL3. The fourth material layer ML4 may contain ITO.

Thereafter, as illustrated in FIG. 14, a second photoresist pattern PR2 may be located on the fourth material layer ML4. The second photoresist pattern PR2 may have a forward taper shape. For example, the second photoresist pattern PR2 may have a width that gradually decreases along the third direction DR3. The second photoresist pattern PR2 may be formed as a positive photoresist.

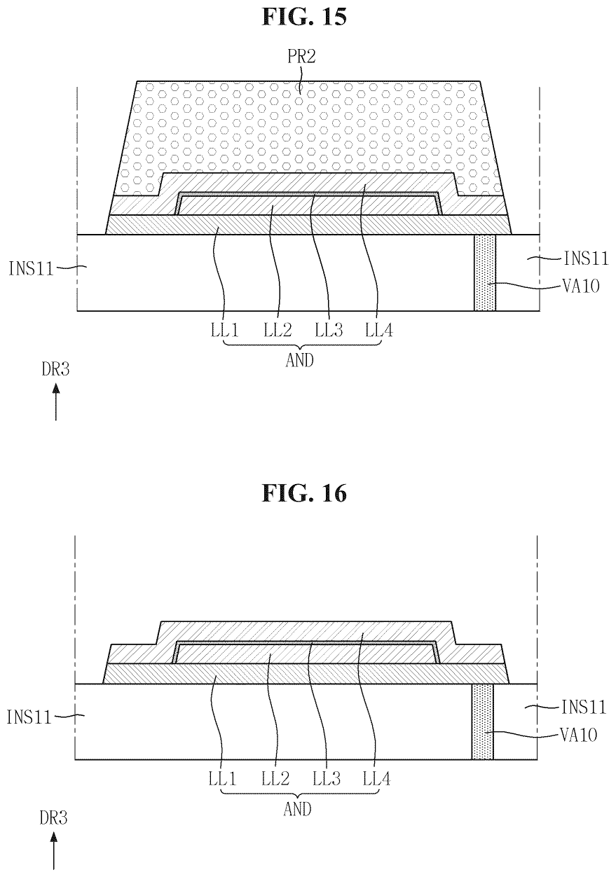

Next, as illustrated in FIG. 15, the fourth material layer ML4 and the first material layer ML1 may be removed using the second photoresist pattern PR2 as a mask. For example, a portion of the fourth material layer ML4 and the first material layer ML1 that is not covered by the second photoresist pattern PR2 and is exposed may be removed by an etchant. As each of the portion of the fourth material layer ML4 and the second material layer ML2 is removed by the etching process in which the second photoresist pattern PR2 is used as a mask, a fourth layer LL4 and the second layer LL2 may be formed. Accordingly, the anode electrode AND including the first layer LL1, the second layer LL2, the third layer LL3, and the fourth layer LL4 may be formed.

Thereafter, as illustrated in FIG. 16, the second photoresist pattern PR2 may be removed. The second photoresist pattern PR1 may be removed by a stripper.

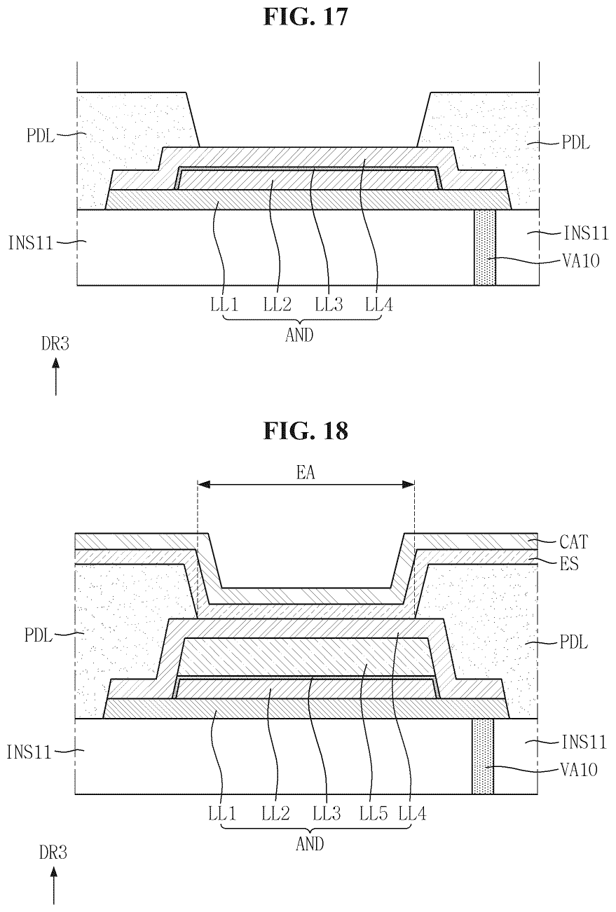

Subsequently, as illustrated in FIG. 17, a pixel-defining film PDL may be located on the anode electrode AND. For example, the pixel-defining film PDL may be located on the fourth layer LL4 of the anode electrode AND.

Next, as illustrated in FIG. 18, a light-emitting stack ES may be located on the anode electrode AND and the pixel-defining film PDL, and a cathode electrode CAT may be located on the light-emitting stack ES.

FIG. 18 is a cross-sectional view of a display device according to one or more other embodiments.

The display device of FIG. 18 is different from the display device of FIG. 7 described above in that the anode electrode AND further includes a fifth layer LL5, and this difference will be mainly described as below.

As illustrated in FIG. 18, the anode electrode AND may include a first layer LL1, a second layer LL2, a third layer LL3, a fourth layer LL4, and a fifth layer LL5. Here, the fifth layer LL5 may be located between the third layer LL3 and the fourth layer LL4. The fifth layer LL5 may contain an inorganic layer.

The fifth layer LL5 of the anode electrode AND may be surrounded by the third layer LL3 and the fourth layer LL4. The third layer LL3 may be located on the lower surface of the fifth layer LL5, and the fourth layer LL4 may be located on the upper surface and the side surfaces of the fifth layer LL5.

One end of the fifth layer LL5 and one end of the second layer LL2 may be located to correspond to each other, and the other end of the fifth layer and the other end of the second layer LL2 may be located to correspond to each other. Accordingly, in plan view, the edge of the fifth layer LL5 and the edge of the second layer LL2 may overlap each other.

Resonance distance for each pixel may become different due to the fifth layer LL5, and this is described in detail with reference to FIG. 18 as below.

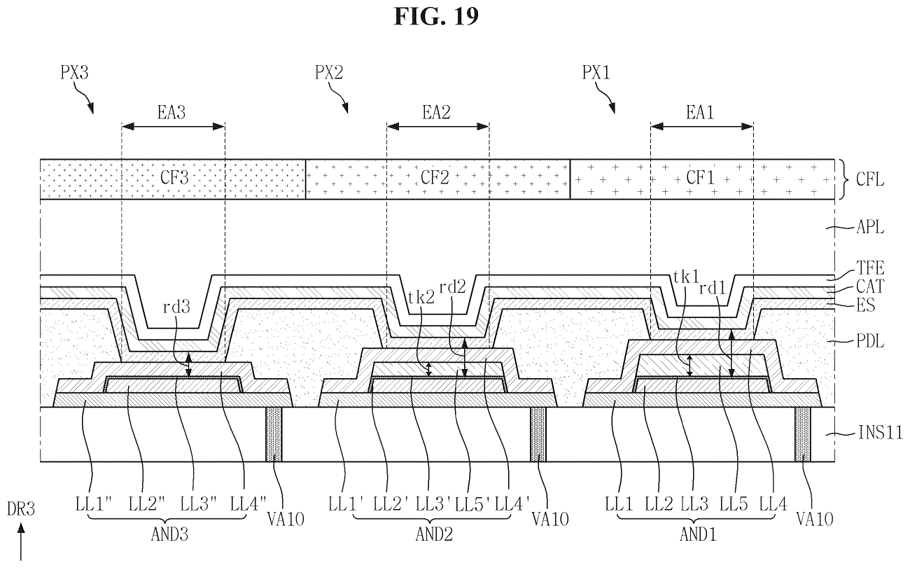

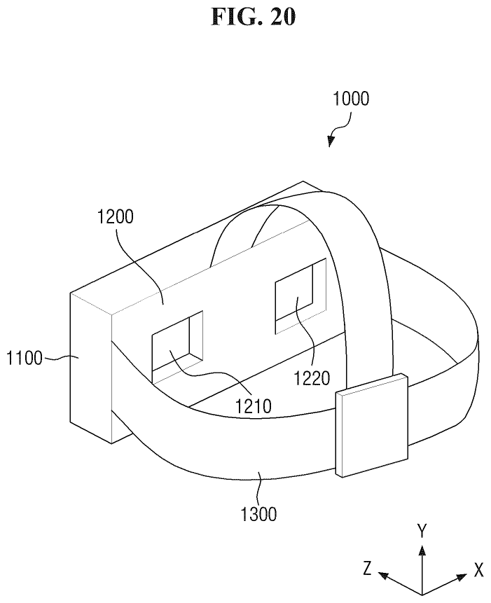

FIG. 19 is a diagram for describing a resonance distance for each pixel in a display device according to one or more embodiments.

As illustrated in FIG. 19, a first pixel PX1 may include a first anode electrode AND1 and a first color filter CF1, a second pixel PX2 may include a second anode electrode AND2 and a second color filter CF2, and a third pixel PX3 may include a third anode electrode AND3 and a third color filter CF3.

The first anode electrode AND1 may be located to correspond to the first color filter CF1. The first anode electrode AND1 may include the first layer LL1, the second layer LL2, the third layer LL3, the fourth layer LL4, and the fifth layer LL5.

The second anode electrode AND2 may be located to correspond to the second color filter CF2. The second anode electrode AND2 may include the first layer LL1′, the second layer LL2′, the third layer LL3′, the fourth layer LL4′, and the fifth layer LL5′. A thickness tk2 of the fifth layer LL5′ of the second anode electrode AND2 may be different from a thickness tk1 of the fifth layer LL5 of the first anode electrode AND1. For example, when defining the thickness tk1 of the fifth layer LL5 of the first anode electrode AND1 as a first thickness tk1, and defining the thickness tk2 of the fifth layer LL5′ of the second anode electrode AND2 as a second thickness tk2, the second thickness tk2 may be less than the first thickness tk1. According to one or more embodiments, the first thickness tk1 may be double the second thickness tk2. Here, the thickness may mean the size in the third direction DR3.

The third anode electrode AND3 may be located to correspond to the third color filter CF3. The third anode electrode AND3 may include the first layer LL1″, the second layer LL2″, the third layer LL3″, and the fourth layer LL4″. For example, the third anode electrode AND3 may not include a fifth layer LL5. In other words, the thickness of the fifth layer of the third anode electrode AND3 may be zero.

As described above, because the first pixel PX1, the second pixel PX2, and the third pixel PX3 include the fifth layer LL5/LL5′ of different thickness, resonance distance in each of the first pixel PX1, the second pixel PX2, and the third pixel PX3 may become different. For example, the resonance distance rd1 (hereinafter, first resonance distance) of the first pixel PX1 may be the greatest, the resonance distance rd3 (hereinafter, third resonance distance) of the third pixel PX3 may be the smallest, and the resonance distance rd2 (hereinafter, second resonance distance) of the second pixel PX2 may be greater than the third resonance distance rd3 and less than the first resonance distance rd1. Here, the resonance distance may mean a distance in the third direction DR3.

Each of the resonance distances rd1, rd2, and rd3 may be defined as a distance between the anode electrode AND1, AND2, and AND3 of the respective pixels PX1, PX2, and PX3 and the cathode electrode CAT. For example, the first resonance distance rd1 may be defined as a distance between the second layer LL2 of the first anode electrode AND1 and the cathode electrode CAT, the second resonance distance rd2 may be defined as a distance between the second layer LL2′ of the second anode electrode AND2 and the cathode electrode CAT, and the third resonance distance rd3 may be defined as a distance between the second layer LL2″ of the third anode electrode AND3 and the cathode electrode CAT.

Accordingly, the micro-cavity (or thin film resonance) effect on light may increase and/or may be optimized depending on the wavelength of light to be emitted from each pixel PX1, PX2, and PX3 and the corresponding resonance distance and/or resonance order. For example, light of a first color, light of a second color, and light of a third color may be appropriately amplified in the first emission area EA1, the second emission area EA2, and the third emission area EA3, respectively. As one or more embodiments, light of the first color emitted through the first emission area EA1 may be red light corresponding to the first color filter CF1, light of the second color emitted through the second emission area EA2 may be green light corresponding to the second color filter CF2, and light of the third color emitted through the third emission area EA3 may be blue light corresponding to the third color filter CF3. In other words, the second resonance distance rd2 of the second emission area EA2, which emits green light, may be less than the first resonance distance rd1 of the first emission area EA1, which emits the red light, and may be greater than the third resonance distance rd3 of the third emission area EA3, which emits blue light.

According to one or more embodiments, the above-described fifth layer LL5 of FIG. 18 is formed through a photolithography process and an etching process of an inorganic layer (e.g., material layer of the fifth layer LL5) after forming the third layer LL3. For example, the fifth layer LL5 may be formed by patterning the inorganic layer located on the third layer LL3 after the process of FIG. 12 described above. For example, the formation process of the fifth layer LL5 may be performed between the process of FIG. 12 and the process of FIG. 13. Meanwhile, as illustrated in FIG. 19, in case when the thickness of the fifth layer LL5 for each pixel is different from each other, a half-tone mask may be used to form the fifth layers LL5 of different thicknesses. Alternatively, as separate photolithography process and etching process are separately performed after forming the inorganic layer in different heights for each pixel, the fifth layers LL5 having different thickness for each pixel may be sequentially formed.

Meanwhile, the encapsulation layer TFE of FIG. 19 may include the first encapsulation inorganic film TFE1 and the second encapsulation inorganic film TFE2 of FIG. 6 described above.

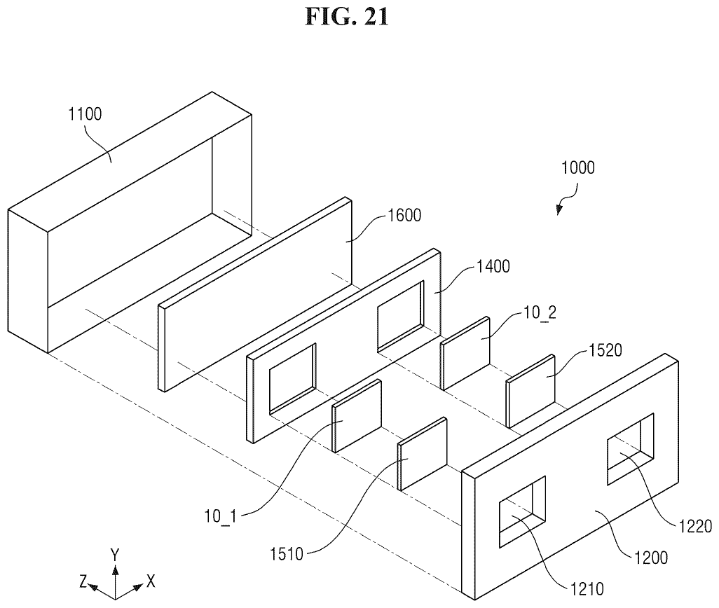

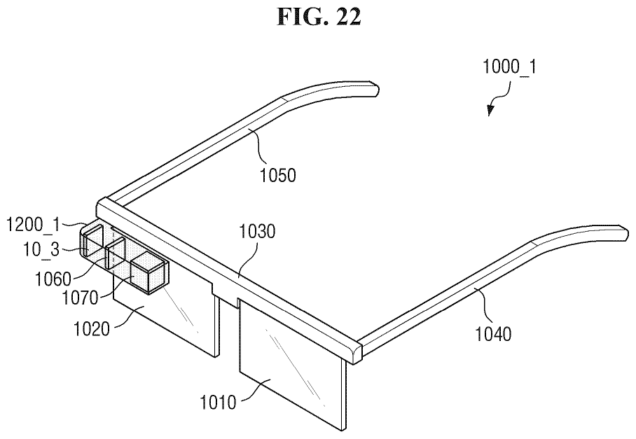

FIG. 20 is a perspective view illustrating a head-mounted display according to one or more embodiments. FIG. 21 is an exploded perspective view illustrating an example of the head-mounted display of FIG. 20.

Referring to FIGS. 20 and 21, a head-mounted display device 1000 according to one or more embodiments includes a first display device 10_1, a second display device 10_2, a display device housing portion 1100, a housing portion cover 1200, a first eyepiece 1210, a second eyepiece 1220, a head-mounted band 1300, a middle frame 1400, a first optical member 1510, a second optical member 1520, and a control circuit board 1600.

The first display device 10_1 provides an image to a user's left eye, and the second display device 10_2 provides an image to a user's right eye. Each of the first display device 10_1 and the second display device 10_2 is substantially the same as the display device 10 described with reference to FIGS. 1 to 19, and a repetitive description of the first display device 10_1 and the second display device 10_2 is thus omitted.

The first optical member 1510 may be located between the first display device 10_1 and the first eyepiece 1210. The second optical member 1520 may be located between the second display device 10_2 and the second eyepiece 1220. Each of the first optical member 1510 and the second optical member 1520 may include at least one convex lens.

The middle frame 1400 may be located between the first display device 10_1 and the control circuit board 1600, and may be located between the second display device 10_2 and the control circuit board 1600. The middle frame 1400 serves to support and fix the first display device 10_1, the second display device 10_2, and the control circuit board 1600.

The control circuit board 1600 may be located between the middle frame 1400 and the display device housing portion 1100. The control circuit board 1600 may be connected to the first display device 10_1 and the second display device 10_2 through a connector. The control circuit board 1600 may convert an image source input from the outside into digital video data DATA, and may transmit the digital video data DATA to the first display device 10_1 and the second display device 10_2 through the connector.

The control circuit board 1600 may transmit digital video data DATA corresponding to a left eye image optimized for the user's left eye to the first display device 10_1, and may transmit digital video data DATA corresponding to a right eye image optimized for the user's right eye to the second display device 10_2. Alternatively, the control circuit board 1600 may transmit the same digital video data DATA to the first display device 10_1 and the second display device 10_2.

The display device housing portion 1100 serves to house the first display device 10_1, the second display device 10_2, the middle frame 1400, the first optical member 1510, the second optical member 1520, and the control circuit board 1600. The housing portion cover 1200 is located to cover opened one surface of the display device housing portion 1100. The housing portion cover 1200 may include the first eyepiece 1210 on which the user's left eye is located and the second eyepiece 1220 on which the user's right eye is located. It has been illustrated in FIGS. 20 and 21 that the first eyepiece 1210 and the second eyepiece 1220 are separately located, but the present disclosure is not limited thereto. The first eyepiece 1210 and the second eyepiece 1220 may be merged as one eyepiece.

The first eyepiece 1210 may be aligned with the first display device 10_1 and the first optical member 1510, and the second eyepiece 1220 may be aligned with the second display device 10_2 and the second optical member 1520. Accordingly, a user may view an image of the first display device 10_1 magnified as a virtual image by the first optical member 1510 through the first eyepiece 1210, and may view an image of the second display device 10_2 magnified as a virtual image by the second optical member 1520 through the second eyepiece 1220.

The head-mounted band 1300 serves to fix the display device housing portion 1100 to a user's head so that the first eyepiece 1210 and the second eyepiece 1220 of the housing portion cover 1200 may be maintained in a state where they are located on the user's left eye and right eye, respectively. When the display device housing portion 1200 is implemented to have a light weight and a small size, the head-mounted display device 1000 may include an eyeglass frame as illustrated in FIG. 22 instead of the head-mounted band 800.

In addition, the head-mounted display device 1000 may further include a battery for supplying power, an external memory slot for housing an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a wireless fidelity (WiFi®) module, or a Bluetooth® module (Bluetooth® being a registered trademark of Bluetooth Sig, Inc., Kirkland, WA, Wi-Fi® being a registered trademark of the non-profit Wi-Fi Alliance).

FIG. 22 is a perspective view illustrating a head-mounted display according to one or more other embodiments.

Referring to FIG. 22, a head-mounted display device 1000_1 according to one or more other embodiments may be a glasses-type display device in which a display device housing portion 1200_1 is implemented to have a light weight and a small size. The head-mounted display device 1000_1 according to one or more other embodiments may include a display device 10_3, a left eye lens 1010, a right eye lens 1020, a support frame 1030, glasses frame legs 1040 and 1050, an optical member 1600, an optical path conversion member 1070, and a display device housing portion 1200_1.

The display device housing portion 1200_1 may include the display device 10_3, the optical member 1600, and the optical path conversion member 1070. An image displayed on the display device 10_3 may be magnified by the optical member 1600, converted in an optical path by the optical path conversion member 1070, and provided to a user's right eye through the right eye lens 1020. For this reason, a user may view an augmented reality image in which a virtual image displayed on the display device 10_3 through his/her right eye and a real image seen through the right eye lens 1020 are combined with each other.

It has been illustrated in FIG. 22 that the display device housing portion 1200_1 is located at a right end of the support frame 1030, but the present disclosure is not limited thereto. For example, the display device housing portion 1200_1 may be located at a left end of the support frame 1030, and in this case, an image of the display device 10_3 may be provided to a user's left eye. Alternatively, the display device housing portions 1200_1 may be located at both the left and right ends of the support frame 1030, and in this case, the user may view an image displayed on the display device 10_3 through both his/her left and right eyes.

It will be able to be understood by one of ordinary skill in the art to which the present disclosure belongs that the present disclosure may be implemented in other specific forms without changing the technical spirit or essential features of the present disclosure. Therefore, it is to be understood that the embodiments described above are illustrative rather than being restrictive in all aspects. It is to be understood that the scope of the present disclosure are defined by the claims rather than the detailed description described above and all modifications and alterations derived from the claims and their equivalents fall within the scope of the present disclosure.

What is claimed is:

1. A display device comprising:
a substrate;
an anode electrode above the substrate, and comprising:
a first layer;
a second layer on the first layer;
a third layer on an upper surface and a side surface of the second layer; and
a fourth layer connected to the first layer, and on an upper surface of the first layer, an upper surface of the third layer, and a side surface of the third layer;
a light-emitting stack above the anode electrode; and
a cathode electrode above the light-emitting stack.

2. The display device of claim 1, wherein the second layer and the third layer are surrounded by the first layer and the fourth layer.

3. The display device of claim 1, wherein the first layer is connected to a transistor through a via.

4. The display device of claim 1, wherein the fourth layer is connected to the light-emitting stack.

5. The display device of claim 1, wherein the fourth layer is directly connected to the first layer.

6. The display device of claim 5, wherein the fourth layer is directly connected to the upper surface of the first layer.

7. The display device of claim 1, wherein the second layer is at a central portion of the upper surface of the first layer.

8. The display device of claim 1, wherein the first layer contains titanium,
wherein the second layer contains aluminum,
wherein the third layer contains aluminum oxide, and
wherein the fourth layer contains a transparent conductive material.

9. The display device of claim 8, wherein the transparent conductive material comprises indium tin oxide.

10. The display device of claim 1, wherein the anode electrode further comprises a fifth layer between the third layer and the fourth layer.

11. The display device of claim 10, wherein the fifth layer comprises an inorganic layer.

12. The display device of claim 11, wherein the anode electrode is provided in plurality and comprises a first anode electrode of a first pixel, a second anode electrode of a second pixel, and a third anode electrode of a third pixel.

13. The display device of claim 12, wherein the fifth layer of the first anode electrode, the fifth layer of the second anode electrode, and the fifth layer of the third anode electrode have different respective thicknesses.

14. The display device of claim 13, further comprising:
a first color filter above the first anode electrode;
a second color filter above the second anode electrode; and
a third color filter above the third anode electrode.

15. The display device of claim 14, wherein the first color filter is configured to transmit red light,
wherein the second color filter is configured to transmit green light, and
wherein the third color filter is configured to transmit blue light.

16. The display device of claim 15, wherein the thickness of the fifth layer of the second anode electrode is less than the thickness of the fifth layer of the first anode electrode, and is greater than the thickness of the fifth layer of the third anode electrode.

17. A method of fabricating a display device, the method comprising:
forming an insulating layer above a substrate;
forming a first material layer above the insulating layer;
forming a first photoresist pattern having a side surface of a reverse tapered shape above the first material layer;
forming a second material layer comprising a first sub-material layer above the first material layer, and a second sub-material layer above the first photoresist pattern;
forming a third layer above the first sub-material layer and above the second sub-material layer to be separated by the first photoresist pattern;
removing the first photoresist pattern such that a second layer above the first material layer remains;
forming a fourth material layer above the third layer;
forming a second photoresist pattern above the fourth material layer;
selectively removing the fourth material layer and the first material layer using the second photoresist pattern as a mask such that a fourth layer and a first layer remain;
removing the second photoresist pattern such that an anode electrode comprising the first layer, the second layer, the third layer, and the fourth layer remains;
forming a pixel-defining film above the anode electrode;
forming a light-emitting stack above the pixel-defining film and the anode electrode; and
forming a cathode electrode above the light-emitting stack.

18. The method of claim 17, wherein the second layer is on the first layer,
wherein the third layer is on an upper surface and a side surface of the second layer, and
wherein the fourth layer is on an upper surface of the first layer, an upper surface of the third layer, and a side surface of the third layer.

19. The method of claim 17, wherein the second layer and the third layer are surrounded by the first layer and the fourth layer.

20. The method of claim 17, wherein the fourth layer is directly connected to the first layer.

21. The method of claim 20, wherein the fourth layer is directly connected to an edge of the first layer.

22. The method of claim 17, wherein the second layer is at a central portion of an upper surface of the first layer.

23. The method of claim 17, wherein the first layer contains titanium,
wherein the second layer contains aluminum,
wherein the third layer contains aluminum oxide, and
wherein the fourth layer contains a transparent conductive material.

24. The method of claim 17, further comprising forming a fifth layer between the third layer and the fourth layer.

25. The method of claim 24, wherein the fifth layer comprises an inorganic layer.
